(19) United States
(12) Patent Application Publication
(10) Pub. No.: US 2024/0014363 A1
(43) Pub. Date: Jan. 11, 2024

(54) DISPLAY DEVICE

(71) Applicant: Samsung Display Co., LTD., Yongin-si (KR)

(72) Inventor: Do Yeong PARK, Yongin-si (KR)

(73) Assignee: Samsung Display Co., LTD., Yongin-si (KR)

(21) Appl. No.: 18/112,728

(22) Filed: Feb. 22, 2023

(30) Foreign Application Priority Data
Jul. 8, 2022 (KR) 10-2022-0084340

(51) Int. Cl. H01L 33/62; H01L 25/075; H01L 33/44; H01L 33/38

(52) U.S. Cl. CPC H01L 33/62; H01L 25/0753; H01L 33/44; H01L 33/382

(57) ABSTRACT

A display device includes a display area and a non-display area, light emitting elements disposed on a substrate in the display area, an overcoat layer disposed on the light emitting elements and extending from the display area to the non-display area, and a barrier layer disposed on the overcoat layer in the non-display area, wherein the barrier layer is not disposed in the display area and comprises silicon nitride.

### CROSS-REFERENCE TO RELATED APPLICATION(S)

This application claims priority to and benefits of Korean Patent Application No. 10-2022-0084340 under 35 U.S.C. 119, filed on Jul. 8, 2022, in the Korean Intellectual Property Office (KIPO), the entire contents of which are incorporated herein by reference.

### BACKGROUND

### 1. Technical Field

The disclosure relates to a display device.

### 2. Description of the Related Art

The importance of display devices has steadily increased with the development of multimedia technology. In response thereto, various types of display devices such as an organic light emitting display (OLED), a liquid crystal display (LCD) and the like have been used.

A display device is a device for displaying an image, and includes a display panel, such as an organic light emitting display panel or a liquid crystal display panel. Among them, the light emitting display panel may include light emitting elements, e.g., light emitting diodes (LED), and examples of the light emitting diode include an organic light emitting diode (OLED) using an organic material as a light-emitting material and an inorganic light emitting diode using an inorganic material as a light-emitting material.

### SUMMARY

Aspects of the disclosure provide a display device capable of preventing external moisture from permeating inside.

However, aspects of the disclosure are not restricted to those set forth herein. The above and other aspects of the disclosure will become more apparent to one of ordinary skill in the art to which the disclosure pertains by referencing the detailed description of the disclosure given below.

According to an aspect of the disclosure, a display device may include a display area and a non-display area, light emitting elements disposed on a substrate in the display area, an overcoat layer disposed on the light emitting elements and extending from the display area to the non-display area, and a barrier layer disposed on the overcoat layer in the non-display area. The barrier layer nay be not disposed in the display area and may include silicon nitride.

In an embodiment, the non-display area may include a pad portion in which pad electrodes are disposed, and the barrier layer may be not disposed in the pad portion.

In an embodiment, the barrier layer may surround the display area and the pad portion in plan view.

In an embodiment, the pad portion may include a first pad hole exposing the pad electrodes, and a second pad hole overlapping the first pad hole in plan view.

In an embodiment, a width of the first pad hole may be less than a width of the second pad hole in a direction perpendicular to a thickness direction of the substrate.

In an embodiment, the first pad hole may penetrate the overcoat layer, and the second pad hole may penetrate the overcoat layer and the barrier layer.

In an embodiment, the overcoat layer may include a first lateral side corresponding to an inner circumferential surface of the first pad hole, a second lateral side corresponding to an inner circumferential surface of the second pad hole, a first top surface connecting the first lateral side and the second lateral side, and a second top surface parallel to the first top surface and connected to the second lateral side.

In an embodiment, a lateral side of the barrier layer and the second lateral side of the overcoat layer may be aligned and coincide with each other in the second pad hole.

In an embodiment, the barrier layer may contact the second top surface of the overcoat layer.

In an embodiment, the display device may further include a dam and a hole portion, each disposed in the non-display area and surrounding the display area in plan view. The overcoat layer and the barrier layer may overlap the dam and the hole portion in plan view.

In an embodiment, the display device may further include a first capping layer disposed on the light emitting elements, a low refractive layer disposed on the first capping layer, a second capping layer disposed on the low refractive layer, and a color filter layer disposed on the second capping layer.

In an embodiment, the overcoat layer may be disposed on the color filter layer.

In an embodiment, the overcoat layer may be interposed between the color filter layer and the second capping layer.

According to an aspect of the disclosure, a display device may include a display area and a non-display area, light emitting elements disposed on a substrate in the display area, an overcoat layer disposed on the light emitting elements and extending from the display area to the non-display area, and a barrier layer disposed on the overcoat layer in the non-display area. The non-display area may include a pad portion in which pad electrodes are disposed. The barrier layer may not be disposed in the display area, may be disposed in the pad portion of the non-display area, and may include silicon nitride.

In an embodiment, the pad portion may include a pad hole penetrating the overcoat layer and exposing the pad electrodes, and the barrier layer may be disposed in the pad hole.

In an embodiment, the display device may further include a via layer interposed between the substrate and the light emitting elements and extending from the display area to the non-display area. The pad hole may expose a top surface of the via layer.

In an embodiment, the barrier layer may contact the top surface of the via layer in the pad hole.

In an embodiment, the barrier layer may cover a lateral side of the overcoat layer corresponding to an inner circumferential surface of the pad hole and may contact the lateral side of the overcoat layer.

In an embodiment, the display device may further include a first electrode and a second electrode disposed on the substrate and spaced apart from each other, a first insulating layer disposed on the first electrode and the second electrode, a first contact electrode disposed on the first insulating layer and in electrical contact with one ends of the light emitting elements, and a second contact electrode disposed on another ends of the light emitting elements. The light emitting elements may be disposed on the first electrode and the second electrode.

In an embodiment, each of the light emitting elements may include a first semiconductor layer comprising a p-type semiconductor, a second semiconductor layer disposed on the first semiconductor layer and comprising an n-type semiconductor, and an emission layer disposed between the first semiconductor layer and the second semiconductor layer.

In accordance with an embodiment of a display device, the barrier layers may be formed in a non-display area, thereby preventing permeation of external moisture without reducing the luminance of the display area. Accordingly, it is possible to prevent the deterioration of the element and improve display quality.

It should be noted that the effects of the disclosure are not limited to those described above, and other effects of the disclosure will be apparent from the following description.

### BRIEF DESCRIPTION OF THE DRAWINGS

The above and other aspects and features of the disclosure will become more apparent by describing in detail embodiments thereof with reference to the attached drawings, in which:

FIG. 1 is a schematic plan view of a display device according to one embodiment;

FIG. 2 is a plan view illustrating one pixel of a display device according to one embodiment;

FIG. 3 is a schematic cross-sectional view taken along line E1-E1′ of FIG. 2;

FIG. 4 is a schematic cross-sectional view taken along line E2-E2′ of FIG. 2;

FIG. 5 is a schematic diagram of a light emitting element according to one embodiment;

FIG. 6 is a schematic cross-sectional view of a display device according to one embodiment;

FIG. 7 is a plan view schematically illustrating a display device according to one embodiment;

FIG. 8 is a schematic cross-sectional view taken along line A1-A1′ of FIG. 7;

FIG. 9 is a plan view schematically illustrating a barrier layer of a display device according to one embodiment;

FIG. 10 is a schematic cross-sectional view taken along line A2-A2′ of FIG. 7;

FIG. 11 is an enlarged view of area A of FIG. 10;

FIGS. 12 to 16 are schematic cross-sectional views illustrating each manufacturing process of a display device according to one embodiment;

FIGS. 17 and 18 are schematic cross-sectional views schematically illustrating a display device according to another embodiment; and

FIG. 19 is a schematic cross-sectional view illustrating a display device according to still another embodiment.

### DETAILED DESCRIPTION OF THE EMBODIMENTS

The disclosure will now be described more fully hereinafter with reference to the accompanying drawings, in which embodiments of the disclosure are shown. The disclosure may, however, be embodied in different forms and should not be construed as limited to the embodiments set forth herein. Rather, these embodiments are provided so that this disclosure will be more thorough and complete, and will fully convey the scope of the disclosure to those skilled in the art.

When an element, such as a layer, is referred to as being “on”, “connected to”, or “coupled to” another element or layer, it may be directly on, connected to, or coupled to the other element or layer or intervening elements or layers may be present. When, however, an element or layer is referred to as being “directly on”, “directly connected to”, or “directly coupled to” another element or layer, there are no intervening elements or layers present. To this end, the term “connected” may refer to physical, electrical, and/or fluid connection, with or without intervening elements. Also, when an element is referred to as being “in contact” or “contacted” or the like to another element, the element may be in “electrical contact” or in “physical contact” with another element; or in “indirect contact” or in “direct contact” with another element. The same reference numbers indicate the same components throughout the specification.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the disclosure. Similarly, the second element could also be termed the first element.

In the specification and the claims, the phrase “at least one of” is intended to include the meaning of “at least one selected from the group of” for the purpose of its meaning and interpretation. For example, “at least one of A and B” may be understood to mean “A, B, or A and B.”

Each of the features of the various embodiments of the disclosure may be combined or combined with each other, in part or in whole, and technically various interlocking and driving are possible. Each embodiment may be implemented independently of each other or may be implemented together in an association.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

Hereinafter, embodiments of the disclosure will be described with reference to the attached drawings.

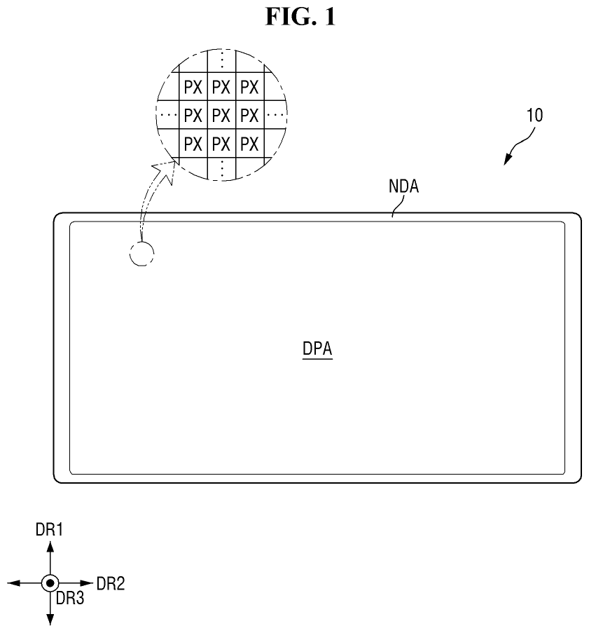

FIG. 1 is a schematic plan view of a display device according to one embodiment.

Referring to FIG. 1, a display device 10 may display a moving image or a still image. The display device 10 may be any electronic device providing a display screen. Examples of the display device 10 may include a television, a laptop computer, a monitor, a billboard, an Internet-of-Things device, a mobile phone, a smartphone, a tablet personal computer (PC), an electronic watch, a smart watch, a watch phone, a head-mounted display, a mobile communication terminal, an electronic notebook, an electronic book, a portable multimedia player (PMP), a navigation device, a game machine, a digital camera, a camcorder and the like, which provide a display screen.

The display device 10 may include a display panel which provides a display screen. Examples of the display panel may include an inorganic light emitting diode display panel, an organic light emitting display panel, a quantum dot light emitting display panel, a plasma display panel, and a field emission display panel. In the following description, a case where an inorganic light emitting diode display panel is applied as a display panel will be described, but the disclosure is not limited thereto, and other display panels may be applied within the scope of the same technical ideas.

The shape of the display device 10 may be variously modified. For example, the display device 10 may have a shape such as a rectangular shape elongated in a horizontal direction, a rectangular shape elongated in a vertical direction, a square shape, a quadrilateral shape with rounded corners (vertices), another polygonal shape, and a circular shape in plan view. The shape of a display area DPA of the display device 10 may be similar to the overall shape of the display device 10. FIG. 1 illustrates a display device 10 having a rectangular shape elongated in a second direction DR2.

The display device 10 may include the display area DPA and a non-display area NDA. The display area DPA may be an area where a screen can be displayed, and the non-display area NDA may be an area where a screen is not displayed. The display area DPA may be referred to as an active region, and the non-display area NDA may be referred to as a non-active region. The display area DPA may substantially occupy the center of the display device 10.

The display area DPA may include multiple pixels PX. The pixels PX may be arranged in a matrix. The shape of each pixel PX may be a rectangular or square shape in plan view. However, the disclosure is not limited thereto, and it may be a rhombic shape in which each side is inclined with respect to one direction. The pixels PX may be alternately disposed in a stripe type or an island type. Each of the pixels PX may include one or more light emitting elements that emit light of a specific wavelength band to display a specific color.

The non-display area NDA may be disposed adjacent to the display area DPA. The non-display area NDA may completely or partially surround the display area DPA. The display area DPA may have a rectangular shape, and the non-display area NDA may be disposed adjacent to four sides of the display area DPA. The non-display area NDA may form a bezel of the display device 10. Wirings or circuit drivers included in the display device 10 may be disposed in the non-display area NDA, or external devices may be mounted thereon.

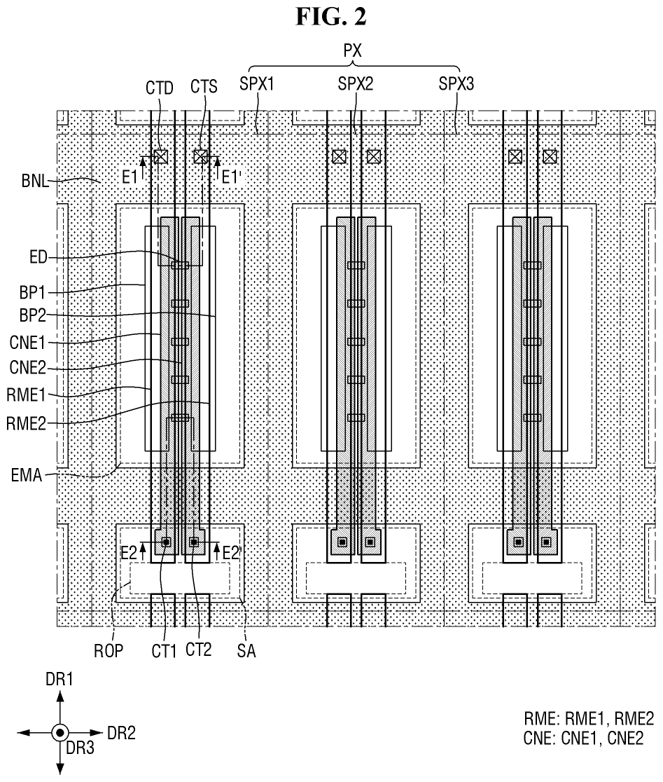

FIG. 2 is a plan view illustrating one pixel of a display device according to an embodiment. FIG. 2 illustrates planar arrangement of electrodes RME (RME1 and RME2), bank patterns BP1 and BP2, a bank layer BNL, multiple light emitting elements ED (ED1 and ED2), and connection electrodes CNE (CNE1 and CNE2) disposed in one pixel PX of the display device 10.

Referring to FIG. 2, each of the pixels PX of the display device 10 may include multiple sub-pixels SPXn. For example, one pixel PX may include a first sub-pixel SPX1, a second sub-pixel SPX2, and a third sub-pixel SPX3. The first sub-pixel SPX1 may emit light of a first color, the second sub-pixel SPX2 may emit light of a second color, and the third sub-pixel SPX3 may emit light of a third color. For example, the first color may be red, the second color may be green, and the third color may be blue. However, the disclosure is not limited thereto, and the sub-pixels SPXn may emit light of a same color. In one embodiment, each of the sub-pixels SPXn may emit blue light. Although FIG. 2 illustrates that one pixel PX includes three sub-pixels SPXn, the disclosure is not limited thereto, and the pixel PX may include a larger number of sub-pixels SPXn.

Each sub-pixel SPXn of the display device 10 may include an emission area EMA and a non-emission area. The emission area EMA may be an area in which the light emitting element ED is disposed to emit light of a specific wavelength band. The non-emission area may be an area in which the light emitting element ED is not disposed and an area from which light is not emitted because light emitted from the light emitting element ED does not reach the area.

The emission area EMA may include an area in which the light emitting element ED is disposed, and an area adjacent to the light emitting element ED in which the lights emitted from the light emitting element ED are emitted. For example, the emission area EMA may include an area in which the light emitted from the light emitting element ED is reflected or refracted by another member and emitted. The light emitting elements ED may be disposed in each sub-pixel SPXn, and the emission area may be formed to include an area where the light emitting elements ED are disposed and an area adjacent thereto.

Although it is shown in the drawing that the sub-pixels SPXn have the emission areas EMA that are substantially identical in size, the disclosure is not limited thereto. In some embodiments, the emission areas EMA of the sub-pixels SPXn may have different sizes according to a color or wavelength band of light emitted from the light emitting element ED disposed in each sub-pixel.

Each sub-pixel SPXn may further include a sub-region SA disposed in the non-emission area. The sub-region SA of the corresponding sub-pixel SPXn may be disposed on a lower side of the emission area EMA, which is another side in the first direction DR1. The emission area EMA and the sub-region SA may be alternately arranged along the first direction DR1, and the sub-region SA may be disposed between the emission areas EMA of adjacent sub-pixels SPXn in the first direction DR1. For example, the emission area EMA and the sub-region SA may be alternately arranged in the first direction DR1, and each of the emission area EMA and the sub-region SA may be repeatedly arranged in the second direction DR2. However, the disclosure is not limited thereto, and the arrangement of the emission areas EMA and the sub-regions SA in the pixels PX may be different from that shown in FIG. 2.

Light may not be emitted from the sub-region SA because the light emitting element ED is not disposed in the sub-region SA, and an electrode RME disposed in each sub-pixel SPXn may be partially disposed in the sub-region SA. The electrodes RME disposed in adjacent sub-pixels SPXn may be separated at a separation portion ROP of the sub-region SA.

The display device 10 may include multiple electrodes RME (RME1 and RME2), the bank patterns BP1 and BP2, the bank layer BNL, the light emitting elements ED, and the connection electrodes CNE (CNE1 and CNE2).

Multiple bank patterns BP1 and BP2 may be disposed in the emission area EMA of each sub-pixel SPXn. The bank patterns BP1 and BP2 may have a width in the second direction DR2 and may extend in the first direction DR1.

For example, the bank patterns BP1 and BP2 may include a first bank pattern BP1 and a second bank pattern BP2 spaced apart from each other in the second direction DR2 in the emission area EMA of each sub-pixel SPXn. The first bank pattern BP1 may be disposed on the left side with respect to the center of the emission area EMA, which is a side in the second direction DR2, and the second bank patterns BP2 may be disposed on the right side with respect to the center of the emission area EMA, which is another side in the second direction DR2, while being spaced apart from the first bank pattern BP1. The first bank pattern BP1 and the second bank pattern BP2 may be alternately disposed along the second direction DR2 and may be disposed in an island-like pattern in the display area DPA. The light emitting elements ED may be arranged between the first bank pattern BP1 and the second bank pattern BP2.

The lengths of the first bank pattern BP1 and the second bank pattern BP2 in the first direction DR1 may be the same, and may be less than the length of the emission area EMA surrounded by the bank layer BNL in the first direction DR1. The first bank pattern BP1 and the second bank pattern BP2 may be spaced apart from the bank layer BNL in the first direction DR1. However, the disclosure is not limited thereto, and the bank patterns BP1 and BP2 may be integrated with the bank layer BNL, or may partially overlap a portion of the bank layer BNL extending in the second direction DR2. The lengths of the bank patterns BP1 and BP2 in the first direction DR1 may be greater than or equal to the length of the emission area EMA surrounded by the bank layer BNL in the first direction DR1.

The widths of the first bank pattern BP1 and the second bank pattern BP2 in the second direction DR2 may be the same. However, the disclosure is not limited thereto, and they may have different widths. For example, one bank pattern may have a larger width than another bank pattern, and the bank pattern having a larger width may be disposed across the emission areas EMA of adjacent sub-pixels SPXn in the second direction DR2. In the bank pattern disposed across the emission areas EMA, a portion of the bank layer BNL extending in the first direction DR1 may overlap the second bank pattern BP2 in the thickness direction. Although it is illustrated in the drawing that two bank patterns BP1 and BP2 having the same width are arranged for each sub-pixel SPXn, the disclosure is not limited thereto. The number and the shape of the bank patterns BP1 and BP2 may vary depending on the number or the arrangement of the electrodes RME.

The electrodes RME (RME1 and RME2) may have a shape extending in one direction and are disposed in each sub-pixel SPXn. The electrodes RME1 and RME2 may extend in the first direction DR1 to be disposed across the emission area EMA of the sub-pixel SPXn and the sub-region SA, and may be disposed to be spaced apart from each other in the second direction DR2. The electrodes RME may be electrically connected to the light emitting elements ED to be described later. However, the disclosure is not limited thereto, and the electrodes RME may not be electrically connected to the light emitting element ED.

The display device 10 may include a first electrode RME1 and a second electrode RME2 arranged in each sub-pixel SPXn. The first electrode RME1 may be located on the left side with respect to the center of the emission area EMA, and the second electrode RME2 may be located on the right side with respect to the center of the emission area EMA while being spaced apart from the first electrode RME1 in the second direction DR2. The first electrode RME1 may be disposed on the first bank pattern BP1, and the second electrode RME2 may be disposed on the second bank pattern BP2. The first electrode RME1 and the second electrode RME2 may be partially arranged in the corresponding sub-pixel SPXn and the sub-region SA over the bank layer BNL. The first electrode RME1 and the second electrode RME2 of adjacent sub-pixels SPXn in the first direction DR1 may be separated at the separation portion ROP located in the sub-region SA of one sub-pixel SPXn.

Although it is illustrated in the drawing that two electrodes RME have a shape extending in the first direction DR1 for each sub-pixel SPXn, the disclosure is not limited thereto. For example, the display device 10 may have a larger number of electrodes RME disposed in one sub-pixel SPXn, or the electrodes RME may be partially bent and have different widths depending on positions.

The bank layer BNL may surround the sub-pixels SPXn, the emission area EMA, and the sub-region SA in plan view. The bank layer BNL may be disposed between emission areas EMA of adjacent sub-pixels SPXn in the first direction DR1 and the second direction DR2, and may also be disposed between the emission area EMA and the sub-region SA in a sub-pixel SPXn. The sub-pixels SPXn, the emission area EMA, and the sub-region SA of the display device 10 may be the areas defined by the arrangement of the bank layer BNL. The distances between the sub-pixels SPXn, the emission areas EMA, and the sub-regions SA may vary depending on the width of the bank layer BNL.

The bank layer BNL may include portions extending in the first direction DR1 and the second direction DR2 in plan view to be arranged in a grid pattern over the entire surface of the display area DPA. The bank layer BNL may be disposed along the boundaries between the sub-pixels SPXn to define the neighboring sub-pixels SPXn. The bank layer BNL may also be arranged to surround the emission area EMA and the sub-region SA disposed for each sub-pixel SPXn to define them from each other.

The light emitting elements ED may be arranged in the emission area EMA. The light emitting elements ED may be disposed between the bank patterns BP1 and BP2, and may be arranged to be spaced apart from each other in the first direction DR1. In one embodiment, the light emitting elements ED may have a shape extending in one direction, and both ends thereof may be disposed on different electrodes RME. The length of the light emitting element ED may be greater than the distance between the electrodes RME spaced apart from each other in the second direction DR2. The extension direction of the light emitting elements ED may be substantially perpendicular to the first direction DR1 in which the electrodes RME extend. However, the disclosure is not limited thereto, and the light emitting element ED may extend in the second direction DR2 or in a direction oblique to the second direction DR2.

Multiple connection electrodes CNE (CNE1 and CNE2) may be disposed on the electrodes RME and the bank patterns BP1 and BP2. The connection electrodes CNE may have a shape extending in one direction, and may be disposed to be spaced apart from each other. Each of the connection electrodes CNE may be in contact with the light emitting element ED and may be electrically connected to the electrode RME or a conductive layer thereunder.

The connection electrodes CNE may include a first connection electrode CNE1 and a second connection electrode CNE2 disposed in each sub-pixel SPXn. The first connection electrode CNE1 may have a shape extending in the first direction DR1 and may be disposed on the first electrode RME1 or the first bank pattern BP1. The first connection electrode CNE1 may partially overlap the first electrode RME1 and may be disposed across the emission area EMA and the sub-region SA over the bank layer BNL. The second connection electrode CNE2 may have a shape extending in the first direction DR1 and may be disposed on the second electrode RME2 or the second bank pattern BP2. The second connection electrode CNE2 may partially overlap the second electrode RME2 and may be disposed across the emission area EMA and the sub-region SA over the bank layer BNL.

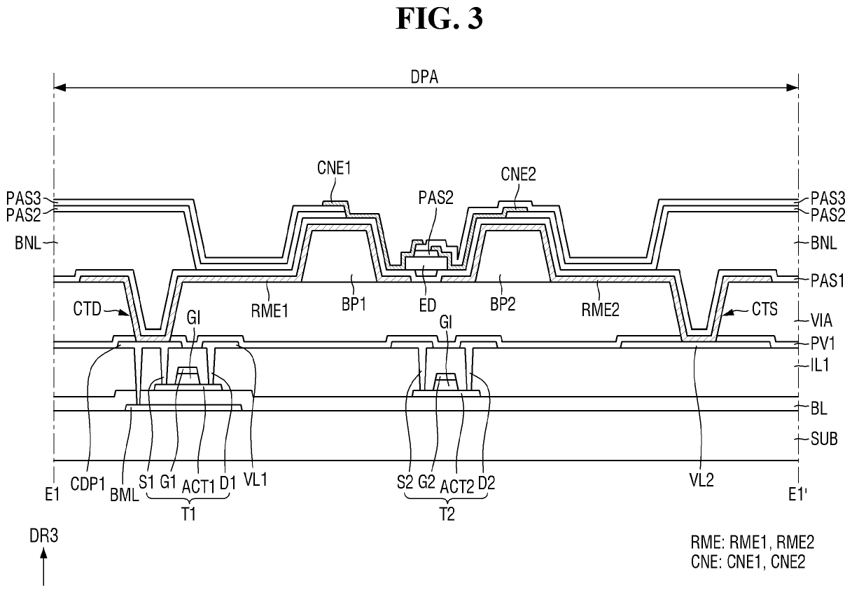

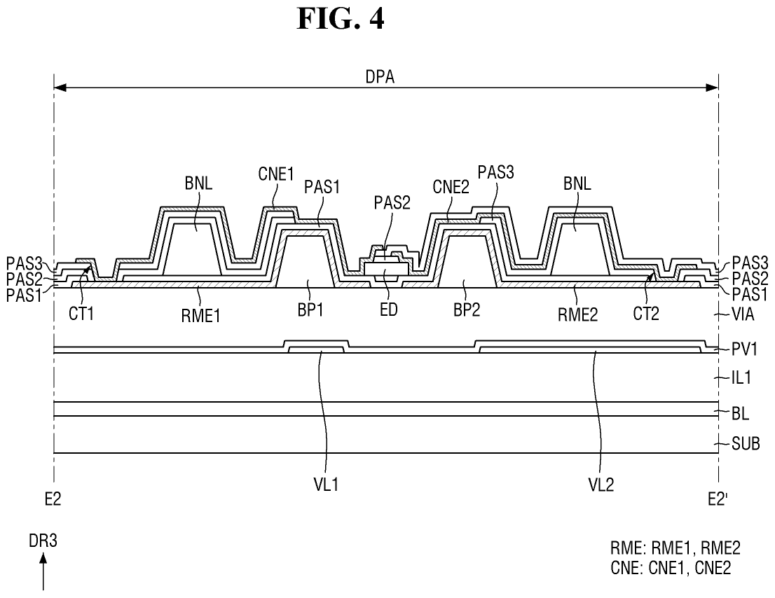

FIG. 3 is a schematic cross-sectional view taken along line E1-E1′ of FIG. 2. FIG. 4 is a schematic cross-sectional view taken along line E2-E2′ of FIG. 2

FIG. 3 illustrates a cross section across both ends of the light emitting element ED and electrode contact holes CTD and CTS disposed in the first sub-pixel SPX1, and FIG. 4 illustrates a cross section across both ends of the light emitting element ED and contact portions CT1 and CT2 disposed in the first sub-pixel SPX1.

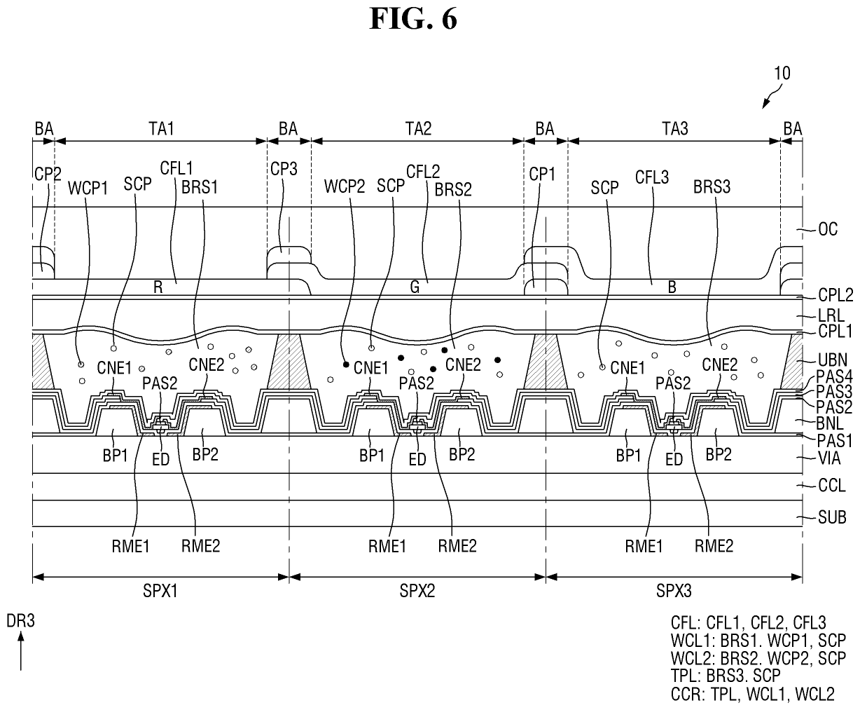

The cross-sectional structure of the display device 10 is described with reference to FIGS. 2 to 4. The display device 10 may include a substrate SUB and a semiconductor layer, multiple conductive layers, and multiple insulating layers disposed thereon. The display device 10 may include the electrodes RME (RME1 and RME2), the light emitting element ED, and the connection electrodes CNE (CNE1 and CNE2). Each of the semiconductor layer, the conductive layer, and the insulating layer may constitute a circuit layer (‘CCL’ in FIG. 6) of the display device 10.

The substrate SUB may be an insulating substrate. The substrate SUB may be made of an insulating material such as glass, quartz, or polymer resin. The substrate SUB may be a rigid substrate, or may be a flexible substrate which can be bent, folded or rolled. The substrate SUB may include the display area DPA and the non-display area NDA surrounding the display area DPA, and the display area DPA may include the emission area EMA and the sub-region SA that is a portion of the non-emission area.

A first conductive layer may be disposed on the substrate SUB. The first conductive layer may include a lower metal layer BML that is disposed to overlap a first active layer ACT1 of a first transistor T1. The lower metal layer BML may prevent light from entering to the first active layer ACT1 of the first transistor T1, or may be electrically connected to the first active layer ACT1 to stabilize electrical characteristics of the first transistor T1. However, the lower metal layer BML may be omitted.

A buffer layer BL may be disposed on the lower metal layer BML and the substrate SUB. The buffer layer BL may be formed on the substrate SUB to protect the transistors of the pixel PX from moisture permeating through the substrate SUB susceptible to moisture permeation, and may perform a surface planarization function.

The semiconductor layer may be disposed on the buffer layer BL. The semiconductor layer may include the first active layer ACT1 of the first transistor T1 and a second active layer ACT2 of the second transistor T2. The first active layer ACT1 and the second active layer ACT2 may be disposed to partially overlap a first gate electrode G1 and a second gate electrode G2 of a second conductive layer to be described later, respectively.

The semiconductor layer may include polycrystalline silicon, monocrystalline silicon, an oxide semiconductor, and the like. In another embodiment, the semiconductor layer may include polycrystalline silicon. The oxide semiconductor may be an oxide semiconductor including indium (In). For example, the oxide semiconductor may include at least one of indium tin oxide (ITO), indium zinc oxide (IZO), indium gallium oxide (IGO), indium zinc tin oxide (IZTO), indium gallium tin oxide (IGTO), indium gallium zinc oxide (IGZO), or indium gallium zinc tin oxide (IGZTO).

Although it is illustrated in the drawing that the first transistor T1 and the second transistor T2 are disposed in the sub-pixel SPXn of the display device 10, the disclosure is not limited thereto and the display device 10 may include a larger number of transistors.

A first gate insulating layer G1 may be disposed on the semiconductor layer in the display area DPA. The first gate insulating layer G1 may serve as a gate insulating layer of each of the transistors T1 and T2. Although it is illustrated in the drawing that the first gate insulating layer G1 is patterned together with the gate electrodes G1 and G2 of the second conductive layer to be described later and partially disposed between the second conductive layer and the active layers ACT1 and ACT2 of the semiconductor layer, the disclosure is not limited thereto. In some embodiments, the first gate insulating layer G1 may be disposed on an entire area of the buffer layer BL.

The second conductive layer may be disposed on the first gate insulating layer G1. The second conductive layer may include a first gate electrode G1 of the first transistor T1 and a second gate electrode G2 of the second transistor T2. The first gate electrode G1 may be disposed to overlap the channel region of the first active layer ACT1 in a third direction DR3 that is a thickness direction, and the second gate electrode G2 may be disposed to overlap the channel region of the second active layer ACT2 in the third direction DR3 that is the thickness direction.

A first interlayer insulating layer IL1 may be disposed on the second conductive layer. The first interlayer insulating layer IL1 may function as an insulating film between the second conductive layer and other layers disposed thereon, and may protect the second conductive layer.

A third conductive layer may be disposed on the first interlayer insulating layer IL1. The third conductive layer may include a first voltage line VL1 and a second voltage line VL2, a first conductive pattern CDP1, a source electrode S1 and a drain electrode D1 of the transistor T1, and a source electrode S2 and a drain electrode D2 of the transistor T2 that are disposed in the display area DPA.

The first voltage line VL1 may be applied with a high potential voltage (or a first power voltage) transmitted to the first electrode RME1, and the second voltage line VL2 may be applied with a low potential voltage (or a second power voltage) transmitted to the second electrode RME2. A portion of the first voltage line VL1 may be in contact with the first active layer ACT1 of the first transistor T1 through a contact hole that passes through the first interlayer insulating layer IL. The first voltage line VL1 may serve as a first drain electrode D1 of the first transistor T1. The second voltage line VL2 may be directly connected to the second electrode RME2 to be described later.

The first conductive pattern CDP1 may be in contact with the first active layer ACT1 of the first transistor T1 through the contact hole penetrating the first interlayer insulating layer IL. The first conductive pattern CDP1 may be in contact with the lower metal layer BML through another contact hole penetrating the first interlayer insulating layer IL1 and the buffer layer BL. The first conductive pattern CDP1 may serve as a first source electrode S1 of the first transistor T1. Further, the first conductive pattern CDP1 may be connected to the first electrode RME1 or the first connection electrode CNE1 to be described later. The first transistor T1 may transmit the first power voltage applied from the first voltage line VL1 to the first electrode RME1 or the first connection electrode CNE1.

The second source electrode S2 and the second drain electrode D2 may be in contact with the second active layer ACT2 of the second transistor T2 through the contact holes penetrating the first interlayer insulating layer IL1.

A first passivation layer PV1 may be disposed on the third conductive layer. The first passivation layer PV1 may function as an insulating layer between the third conductive layer and other layers and may protect the third conductive layer.

The buffer layer BL, the first gate insulating layer G1, the first interlayer insulating layer IL1, and the first passivation layer PV1 described above may be formed of multiple inorganic layers stacked each other in an alternating manner. For example, the buffer layer BL, the first gate insulating layer G1, the first interlayer insulating layer IL1, and the first passivation layer PV1 may be formed as a double layer formed by stacking, or a multilayer formed by alternately stacking, inorganic layers including at least one of silicon oxide (SiOₓ), silicon nitride (SiNₓ), or silicon oxynitride (SiOₓN_{y}). However, the disclosure is not limited thereto, and the buffer layer BL, the first gate insulating layer G1, the first interlayer insulating layer IL1, and the first passivation layer PV1 may be formed as a single inorganic layer including the above-described insulating material. Further, in some embodiments, the first interlayer insulating layer IL1 may be made of an organic insulating material such as polyimide (PI) or the like.

A via layer VIA may be disposed on the third conductive layer in the display area DPA. The via layer VIA may include an organic insulating material, e.g., polyimide (PI), and may compensate the stepped portion formed by the conductive layers disposed thereunder to flatten the top surface. However, in some embodiments, the via layer VIA may be omitted.

The display device 10 may include, as a display element layer disposed on the via layer VIA, the bank patterns BP1 and BP2, the electrodes RME (RME1 and RME2), the bank layer BNL, the light emitting elements ED, and the connection electrodes CNE (CNE1 and CNE2). The display device 10 may include insulating layers PAS1, PAS2, PAS3, and PAS4 disposed on the via layer VIA.

The bank patterns BP1 and BP2 may be disposed on the via layer VIA. For example, each of the bank patterns BP1 and BP2 may be directly disposed on the via layer VIA, and may have a structure in which at least a part thereof protrudes from the top surface of the via layer VIA. The protruding parts of the bank patterns BP1 and BP2 may have an inclined surface or a curved surface with a certain curvature, and the light emitted from the light emitting element ED may be reflected by the electrode RME disposed on the bank patterns BP1 and BP2 and emitted in the upward direction of the via layer VIA. Unlike the embodiment illustrated in the drawing, the bank patterns BP1 and BP2 may have a shape, e.g., a semicircular or semi-elliptical shape, in which the outer surface is curved with a certain curvature in cross-sectional view. The bank patterns BP1 and BP2 may include an organic insulating material such as polyimide (PI), but is not limited thereto.

The electrodes RME (RME1 and RME2) may be disposed on the bank patterns BP1 and BP2 and the via layer VIA. For example, the first electrode RME1 and the second electrode RME2 may be disposed on at least inclined side surfaces of the bank patterns BP1 and BP2. The width of each of the electrodes RME1 and RME2 measured in the second direction DR2 may be less than the width of each of the bank patterns BP1 and BP2 measured in the second direction DR2, and the distance between the first electrode RME1 and the second electrode RME2 in the second direction DR2 may be less than the distance between the bank patterns BP1 and BP2. At least a portion of the first electrode RME1 and the second electrode RME2 may be directly arranged on the via layer VIA, so that the first electrode RME1 and the second electrode RME2 may be arranged on the same plane.

The light emitting element ED disposed between the bank patterns BP1 and BP2 may emit light from both ends, and the emitted light may be directed toward the electrodes RME disposed on the bank patterns BP1 and BP2. The electrodes RME may have a structure in which portions thereof disposed on the bank patterns BP1 and BP2 may reflect the light emitted from the light emitting element ED. The first electrode RME1 and the second electrode RME2 may be arranged to cover at least one side surfaces of the bank patterns BP1 and BP2 and may reflect the light emitted from the light emitting element ED.

The electrodes RME may be in direct contact with the third conductive layer through the electrode contact holes CTD and CTS at the portions overlapping the bank layer BNL between the emission area EMA and the sub-region SA. The first electrode contact hole CTD may be formed in an area in which the bank layer BNL and the first electrode RME1 overlap, and the second electrode contact hole CTS may be formed in an area in which the bank layer BNL and the second electrode RME2 overlap. The first electrode RME1 may be in contact with the first conductive pattern CDP1 through the first electrode contact hole CTD penetrating the via layer VIA and the first passivation layer PV1. The second electrode RME2 may be in contact with the second voltage line VL2 through the second electrode contact hole CTS penetrating the via layer VIA and the first passivation layer PV1. The first electrode RME1 may be electrically connected to the first transistor T1 through the first conductive pattern CDP1, so that the first power voltage may be applied to the first electrode RME1, and the second electrode RME2 may be electrically connected to the second voltage line VL2, so that the second power voltage may be applied to the second electrode RME2. However, the disclosure is not limited thereto. In another embodiment, the electrodes RME1 and RME2 may not be electrically connected to the voltage lines VL1 and VL2 of the third conductive layer, respectively, and the connection electrode CNE to be described later may be directly connected to the third conductive layer.

The electrodes RME may include a conductive material having high reflectivity. For example, the electrodes RME may include a metal such as silver (Ag), copper (Cu), or aluminum (Al), or may include an alloy including aluminum (Al), nickel (Ni), lanthanum (La), or the like. In another example, the electrodes RME may have a structure in which a metal layer such as titanium (Ti), molybdenum (Mo), and niobium (Nb) and the alloy are stacked each other. In some embodiments, the electrodes RME may be formed as a double layer or a multilayer formed by stacking at least one metal layer made of an alloy including aluminum (Al) and titanium (Ti), molybdenum (Mo), and niobium (Nb).

The disclosure is not limited thereto, and each electrode RME may include a transparent conductive material. For example, each electrode RME may include a material such as ITO, IZO, and ITZO. In some embodiments, each of the electrodes RME may have a structure in which at least one transparent conductive material and at least one metal layer having high reflectivity are stacked each other, or may be formed as one layer including them. For example, each electrode RME may have a stacked structure of ITO/Ag/ITO, ITO/Ag/IZO, ITO/Ag/ITZO/IZO, or the like. The electrodes RME may be electrically connected to the light emitting element ED, and may reflect some of the lights emitted from the light emitting element ED to an upward direction of the substrate SUB.

The first insulating layer PAS1 may be disposed on the via layer VIA and the electrodes RME in the entire display area DPA. The first insulating layer PAS1 may include an insulating material to protect the electrodes RME and insulate electrodes RME from each other. The first insulating layer PAS1 may be disposed to cover the electrodes RME before the bank layer BNL is formed, so that it may prevent the electrodes RME from being damaged in a process of forming the bank layer BNL. The first insulating layer PAS1 may prevent the light emitting element ED disposed thereon from being damaged by direct contact with other members.

In an embodiment, the first insulating layer PAS1 may have stepped portions such that the top surface thereof is partially depressed between the electrodes RME spaced apart in the second direction DR2. The light emitting element ED may be disposed on the top surface of the first insulating layer PAS1, where the stepped portions are formed, and thus a space may remain between the light emitting element ED and the first insulating layer PAS1.

The first insulating layer PAS1 may include contact portions CT1 and CT2 disposed in the sub-region SA. Each of the contact portions CT1 and CT2 may be disposed to overlap respective electrodes RME. For example, the contact portions CT1 and CT2 may include a first contact portion CT1 overlapping the first electrode RME1 and a second contact portion CT2 overlapping the second electrode RME2. The first contact portions CT1 and the second contact portions CT2 may penetrate the first insulating layer PAS1 to partially expose the top surface of the first electrode RME1 or the second electrode RME2 thereunder. Each of the first contact portion CT1 and the second contact portion CT2 may also penetrate some of other insulating layers disposed on the first insulating layer PAS1. The electrode RME exposed by each of the contact portions CT1 and CT2 may be in contact with the connection electrode CNE.

The bank layer BNL may be disposed on the first insulating layer PAS1. The bank layer BNL may include portions extending in the first direction DR1 and the second direction DR2, and may surround the sub-pixels SPXn. The bank layer BNL may surround and distinguish the emission area EMA and the sub-region SA of each sub-pixel SPXn, and may surround the outermost portion of the display area DPA and distinguish the display area DPA and the non-display area NDA.

Similar to the bank patterns BP1 and BP2, the bank layer BNL may have a certain height. In some embodiments, the top surface of the bank layer BNL may be higher than that of the bank patterns BP1 and BP2, and the thickness of the bank layer BNL may be equal to or greater than that of the thickness of the bank patterns BP1 and BP2. The bank layer BNL may prevent ink from overflowing to adjacent sub-pixels SPXn in an inkjet printing process during the manufacturing process of the display device 10. Similar to the bank patterns BP1 and BP2, the bank layer BNL may include an organic insulating material such as polyimide.

The light emitting elements ED may be arranged in the emission area EMA. The light emitting elements ED may be disposed on the first insulating layer PAS1 between the bank patterns BP1 and BP2. The light emitting element ED may be disposed such that the direction the light emitting element ED extends is parallel to the top surface of the substrate SUB. As will be described later, the light emitting element ED may include multiple semiconductor layers arranged along one direction in which the light emitting element ED extends, and the semiconductor layers may be sequentially arranged along the direction parallel to the top surface of the substrate SUB. However, the disclosure is not limited thereto, and the semiconductor layers may be arranged in the direction perpendicular to the substrate SUB in case that the light emitting element ED has another structure.

The light emitting elements ED disposed in different sub-pixels SPXn may emit light of different wavelength bands depending on a material constituting the semiconductor layer. However, the disclosure is not limited thereto, and the light emitting elements ED arranged in different sub-pixels SPXn may include the semiconductor layer of the same material and emit light of the same color.

The light emitting elements ED may be electrically connected to the electrode RME and the conductive layers below the via layer VIA while being in contact with the connection electrodes CNE (CNE1 and CNE2), and may emit light of a specific wavelength band by receiving an electrical signal.

The second insulating layer PAS2 may be disposed on the light emitting elements ED, the first insulating layer PAS1, and the bank layer BNL. The second insulating layer PAS2 may include a pattern portion disposed on the light emitting elements ED extending in the first direction DR1 between the bank patterns BP1 and BP2. The pattern portion may partially surround the outer surface of the light emitting element ED, and may not cover both sides or both ends of the light emitting element ED. The pattern portion may form a linear or island-like pattern in each sub-pixel SPXn in plan view. The pattern portion of the second insulating layer PAS2 may protect the light emitting element ED and fix the light emitting elements ED during a manufacturing process of the display device 10. Further, the second insulating layer PAS2 may fill the space between the light emitting element ED and the first insulating layer PAS1. Further, a portion of the second insulating layer PAS2 may be disposed on the bank layer BNL and in the sub-regions SA.

The second insulating layer PAS2 may include the contact portions CT1 and CT2 disposed in the sub-region SA. The second insulating layer PAS2 may include the first contact portion CT1 overlapping the first electrode RME1, and the second contact portion CT2 overlapping the second electrode RME2. The contact portions CT1 and CT2 may penetrate the second insulating layer PAS2 in addition to the first insulating layer PAS1. The first contact portions CT1 and the second contact portions CT2 may partially expose the top surface of the first electrode RME1 or the second electrode RME2 disposed thereunder.

The connection electrodes CNE (CNE1 and CNE2) may be disposed on the electrodes RME and the bank patterns BP1 and BP2. The first connection electrode CNE1 may be disposed on the first electrode RME1 and the first bank pattern BP1. The first connection electrode CNE1 may partially overlap the first electrode RME1 and may be disposed across the emission area EMA and the sub-region SA over the bank layer BNL. The second connection electrode CNE2 may be disposed on the second electrode RME2 and the second bank pattern BP2. The second connection electrode CNE2 may partially overlap the second electrode RME2 and may be disposed across the emission area EMA and the sub-region SA over the bank layer BNL.

Each of the first connection electrode CNE1 and the second connection electrode CNE2 may be disposed on the second insulating layer PAS2 and may be in contact with the light emitting elements ED. The first connection electrode CNE1 may partially overlap the first electrode RME1 and may be in contact with one ends of the light emitting elements ED. The second connection electrode CNE2 may partially overlap the second electrode RME2 and may be in contact with another ends of the light emitting elements ED. The connection electrodes CNE may be disposed across the emission area EMA and the sub-region SA. Portions of the connection electrodes CNE in the emission area EMA may be in contact with the light emitting elements ED, and portions of the connection electrodes CNE in the sub-region SA may be electrically connected to the third conductive layer. The first connection electrode CNE1 may be in contact with a first end of the light emitting element ED, and the second connection electrode CNE2 may be in contact with a second end of the light emitting element ED.

In accordance with one embodiment, in the display device 10, the connection electrodes CNE may be in contact with the electrode RME through the contact portions CT1 and CT2 disposed in the sub-region SA. The first connection electrode CNE1 may be in contract with the first electrode RME1 through the first contact portion CT1 penetrating the first insulating layer PAS1, the second insulating layer PAS2, and the third insulating layer PAS3 in the sub-region SA. The second connection electrode CNE2 may be in contact with the second electrode RME2 through the second contact portion CT2 penetrating the first insulating layer PAS1 and the second insulating layer PAS2 in the sub-region SA. Each of the connection electrodes CNE may be electrically connected to the third conductive layer through each of electrodes RME. The first connection electrode CNE1 may be electrically connected to the first transistor T1, so that the first power voltage may be applied to the first connection electrode CNE1, and the second connection electrode CNE2 may be electrically connected to the second voltage line VL2, so that the second power voltage may be applied to the second connection electrode CNE2. Each connection electrode CNE may be in contact with the light emitting element ED in the emission area EMA to transmit the power voltage to the light emitting element ED.

However, the disclosure is not limited thereto. In some embodiments, the connection electrodes CNE may be in direct contact with the third conductive layer, and may be electrically connected to the third conductive layer through patterns other than the electrodes RME.

The connection electrodes CNE may include a conductive material. For example, the connection electrodes CNE may include ITO, IZO, ITZO, aluminum (Al), or the like. For example, the connection electrodes CNE may include a transparent conductive material, and light emitted from the light emitting element ED may pass through the connection electrodes CNE to be emitted.

The third insulating layer PAS3 may be disposed on the second connection electrode CNE2 and the second insulating layer PAS2. The third insulating layer PAS3 may be disposed on an entire area of the second insulating layer PAS2 to cover the second connection electrode CNE2, and the first connection electrode CNE1 may be disposed on the third insulating layer PAS3. The third insulating layer PAS3 may insulate the first connection electrode CNE1 and the second connection electrode CNE2 to prevent direct contact therebetween.

The third insulating layer PAS3 may include the first contact portions CT1 disposed in the sub-region SA. The first contact portion CT1 may penetrate the third insulating layer PAS3 in addition to the first insulating layer PAS1 and the second insulating layer PAS2. The first contact portions CT1 may partially expose the top surface of the first electrode RME1 disposed thereunder.

Although not illustrated in the drawings, another insulating layer (‘PAS4’ in FIG. 6) may be disposed on the third insulating layer PAS3 and the first connection electrode CNE1. The insulating layer may function to protect the members disposed on the substrate SUB against the external environment.

Each of the first insulating layer PAS1, the second insulating layer PAS2, and the third insulating layer PAS3 described above may include an inorganic insulating material or an organic insulating material. For example, each of the first insulating layer PAS1, the second insulating layer PAS2, and the third insulating layer PAS3 may include an inorganic insulating material. In another example, the first insulating layer PAS1 and the third insulating layer PAS3 may include an inorganic insulating material, and the second insulating layer PAS2 may include an organic insulating material. Each or at least one of the first insulating layer PAS1, the second insulating layer PAS2, and the third insulating layer PAS3 may have a structure in which multiple insulating layers are stacked each other alternately or repeatedly. In an embodiment, each of the first insulating layer PAS1, the second insulating layer PAS2, and the third insulating layer PAS3 may include at least one of silicon oxide (SiOₓ), silicon nitride (SiNₓ), and silicon oxynitride (SiOₓN_{y}). The first insulating layer PAS1, the second insulating layer PAS2, and the third insulating layer PAS3 may be made of a same material or different materials. In another embodiment, some of them may be made of a same material and others may be made of different materials.

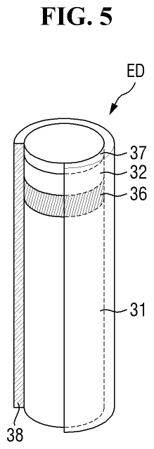

FIG. 5 is a schematic diagram of a light emitting element according to one embodiment.

Referring to FIG. 5, the light emitting element ED may be a light emitting diode. For example, the light emitting element ED may be an inorganic light emitting diode that has a nanometer or micrometer size, and is made of an inorganic material. The light emitting element ED may be aligned between two electrodes each having a polarity in case that an electric field is formed in a specific direction between two electrodes facing each other.

The light emitting element ED according to one embodiment may have a shape elongated in one direction. The light emitting element ED may have a shape of a cylinder, a rod, a wire, a tube, or the like. However, the shape of the light emitting element ED is not limited thereto, and the light emitting element ED may have a polygonal prism shape such as a regular cube, a rectangular parallelepiped, and a hexagonal prism, or may have various shapes such as a shape elongated in one direction and having an outer surface partially inclined.

The light emitting element ED may include a semiconductor layer doped with a conductivity type (e.g., p-type or n-type) dopant. The semiconductor layer may emit light of a specific wavelength band by receiving an electrical signal applied from an external power source. The light emitting element ED may include a first semiconductor layer 31, a second semiconductor layer 32, a light emitting layer 36, an electrode layer 37, and an insulating film 38.

The first semiconductor layer 31 may be an n-type semiconductor. The first semiconductor layer 31 may include a semiconductor material having a chemical formula of AlₓGa_{y}In1_{-x-y}N (0≤x≤1, 0≤y≤1, 0≤x+y≤1). For example, the first semiconductor layer 31 may be at least one of AlGaInN, GaN, AlGaN, InGaN, AlN, and InN doped with an n-type dopant. The n-type dopant doped into the first semiconductor layer 31 may be Si, Ge, Sn, or the like.

The second semiconductor layer 32 may be disposed on the first semiconductor layer 31 with the light emitting layer 36 therebetween. The second semiconductor layer 32 may be a p-type semiconductor, and the second semiconductor layer 32 may include a semiconductor material having a chemical formula of AlₓGa_{y}In1_{-x-y}N (0≤x≤1, 0≤y≤1, 0≤x+y≤1). For example, the second semiconductor layer 32 may be at least one of AlGaInN, GaN, AlGaN, InGaN, AlN, and InN doped with a p-type dopant. The p-type dopant doped into the second semiconductor layer 32 may be Mg, Zn, Ca, Ba, or the like.

Although it is illustrated in the drawing that each of the first semiconductor layer 31 and the second semiconductor layer 32 are configured as one layer, the disclosure is not limited thereto. Depending on the material of the light emitting layer 36, the first semiconductor layer 31 and the second semiconductor layer 32 may include a larger number of layers, such as a cladding layer or a tensile strain barrier reducing (TSBR) layer. For example, the light emitting element ED may further include another semiconductor layer disposed between the first semiconductor layer 31 and the light emitting layer 36 or between the second semiconductor layer 32 and the light emitting layer 36. The semiconductor layer disposed between the first semiconductor layer 31 and the light emitting layer 36 may be at least one of AlGaInN, GaN, AlGaN, InGaN, AlN, InN, and SLs doped with an n-type dopant, and the semiconductor layer disposed between the second semiconductor layer 32 and the light emitting layer 36 may be at least one of AlGaInN, GaN, AlGaN, InGaN, AlN, and InN doped with a p-type dopant.

The light emitting layer 36 may be disposed between the first semiconductor layer 31 and the second semiconductor layer 32. The light emitting layer 36 may include a material having a single or multiple quantum well structure. In case that the light emitting layer 36 includes a material having a multiple quantum well structure, multiple quantum layers and well layers may be stacked each other alternately. The light emitting layer 36 may emit light by coupling of electron-hole pairs in response to an electrical signal applied through the first semiconductor layer 31 and the second semiconductor layer 32. The light emitting layer 36 may include a material such as AlGaN, AlGaInN, or InGaN. For example, in case that the light emitting layer 36 has a multiple quantum well structure in which quantum layers and well layers are alternately stacked each other, the quantum layer may include a material such as AlGaN or AlGaInN, and the well layer may include a material such as GaN or AlInN.

The light emitting layer 36 may have a structure in which semiconductor materials having a large band gap energy and semiconductor materials having a small band gap energy are alternately stacked each other, and may include group III to V semiconductor materials depending on the wavelength band of the emitted light. The light emitted by the light emitting layer 36 is not limited to the light of the blue wavelength band, and the light emitting layer 36 may emit light of a red or green wavelength band in some cases.

The electrode layer 37 may be an ohmic connection electrode. However, the disclosure is not limited thereto, and it may be a Schottky connection electrode. The light emitting element ED may include at least one electrode layer 37. The light emitting element ED may include one or more electrode layers 37, but the disclosure is not limited thereto, and the electrode layer 37 may be omitted.

In the display device 10, in case that the light emitting element ED is electrically connected to an electrode or a connection electrode, the electrode layer 37 may reduce the resistance between the light emitting element ED and the electrode or connection electrode. The electrode layer 37 may include a conductive metal. For example, the electrode layer 37 may include at least one of aluminum (Al), titanium (Ti), indium (In), gold (Au), silver (Ag), ITO, IZO, and ITZO.

The insulating film 38 may be arranged to surround the outer surfaces of the semiconductor layers and electrode layers described above. For example, the insulating film 38 may be disposed to surround at least the outer surface of the light emitting layer 36, and may be formed to expose both ends of the light emitting element ED in the longitudinal direction. In cross-sectional view, the insulating film 38 may have a top surface, which is rounded in a region adjacent to at least one end of the light emitting element ED.

The insulating film 38 may include at least one materials having insulating properties, for example, silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), or titanium oxide (TiOₓ). It is illustrated in the drawing that the insulating film 38 is formed as a single layer, but the disclosure is not limited thereto. In some embodiments, the insulating film 38 may be formed in a multilayer structure having multiple layers stacked each other.

The insulating film 38 may perform a function of protecting the semiconductor layers and the electrode layer of the light emitting element ED. The insulating film 38 may prevent an electrical short circuit that may occur at the light emitting layer 36 in case that an electrode to which an electrical signal is transmitted is in direct contact with the light emitting element ED. The insulating film 38 may prevent a decrease in luminous efficiency of the light emitting element ED.

The insulating film 38 may have an outer surface which is surface-treated. The light emitting elements ED may be aligned by spraying the ink in which the light emitting elements ED are dispersed on the electrodes. The surface of the insulating film 38 may be treated to have a hydrophobic property or hydrophilic property in order to keep the light emitting elements ED in the dispersed state without being aggregated with other adjacent light emitting elements ED in the ink.

According to one embodiment, the display device 10 may further include a color control layer (‘CCR’ in FIG. 6) and a color filter layer (‘CFL’ in FIG. 6) disposed on the light emitting elements ED. Light emitted from the light emitting element ED may be emitted through the color control layer CCR and the color filter layer CFL. Even in case that a same type of the light emitting elements ED are disposed in the respective sub-pixels SPXn, the color of the emitted light may be different for each sub-pixel SPXn.

FIG. 6 is a schematic cross-sectional view of a display device according to one embodiment.

Referring to FIG. 6, the display device 10 may include the light emitting elements ED disposed on the substrate SUB, and the color control layer TPL, WCL1, and WCL2 and the color filter layer CFL that are disposed thereabove. The display device 10 may also include multiple layers disposed between the color control layer CCR and the color filter layer CFL. Hereinafter, the layers disposed on the light emitting elements ED of the display device 10 will be described.

The fourth insulating layer PAS4 may be disposed on the third insulating layer PAS3, the connection electrodes CNE1 and CNE2, and the bank layer BNL. The fourth insulating layer PAS4 may protect the layers disposed on the substrate SUB. However, the fourth insulating layer PAS4 may be omitted.

An upper bank layer UBN, the color control layer CCR, color patterns CP1, CP2 and CP3, and the color filter layer CFL may be disposed on the fourth insulating layer PAS4. Multiple capping layers CPL1 and CPL2, and a low refractive index layer LRL may be disposed between the color control layer CCR and the color filter layer CFL. An overcoat layer OC may be disposed on the color filter layer CFL.

The display device 10 may include light transmitting areas TA1, TA2, and TA3 in which the color filter layer CFL is disposed to emit light and a light blocking area BA disposed between the light transmitting areas TA1, TA2 and TA3 and in which light is not emitted. The light transmitting areas TA1, TA2, and TA3 may be located to correspond to a portion of the emission area EMA of each sub-pixel SPXn, and the light blocking area BA may be an area other than the light transmitting areas TA1, TA2, and TA3.

The upper bank layer UBN may be disposed on the fourth insulating layer PAS4 to overlap the bank layer BNL. The upper bank layer UBN may include portions extending in the first direction DR1 and the second direction DR2 to be disposed in a grid pattern. The upper bank layer UBN may surround the emission area EMA or a portion in which the light emitting elements ED are disposed. The upper bank layer UBN may form a region in which the color control layer CCR is disposed.

The color control layer CCR may be disposed in a region surrounded by the upper bank layer UBN on the fourth insulating layer PAS4. The color control layer CCR may be disposed in the light transmitting areas TA1, TA2, and TA3 surrounded by the upper bank layer UBN to form an island-like pattern in the display area DPA. However, the disclosure is not limited thereto, and each of the color control layers CCR may extend in one direction and may be disposed across the sub-pixels SPXn to form a linear pattern.

In the embodiment in which the light emitting element ED of each sub-pixel SPXn emits blue light of the third color, the color control layer CCR may include the first wavelength conversion layer WCL1 disposed in the first sub-pixel SPX1 to correspond to a first light transmitting area TA1, the second wavelength conversion layer WCL2 disposed in the second sub-pixel SPX2 to correspond to a second light transmitting area TA2, and the light transmitting layer TPL disposed in the third sub-pixel SPX3 to correspond to a third light transmitting area TA3.

The first wavelength conversion layer WCL1 may include a first base resin BRS1 and a first wavelength conversion material WCP1 provided in the first base resin BRS1. The second wavelength conversion layer WCL2 may include a second base resin BRS2 and a second wavelength conversion material WCP2 provided in the second base resin BRS2. The first wavelength conversion layer WCL1 and the second wavelength conversion layer WCL2 may transmit light after converting the wavelength of the blue light incident from the light emitting element ED. The first wavelength conversion layer WCL1 and the second wavelength conversion layer WCL2 may further include a scatterer SCP included in each base resin, and the scatterer SCP may increase wavelength conversion efficiency.

The light transmitting layer TPL may include a third base resin BRS3 and the scatterer SCP included in the third base resin BRS3. The light transmitting layer TPL may transmit the blue light of the third color incident from the light emitting element ED while maintaining the wavelength thereof. The scatterer SCP of the light transmitting layer TPL may serve to control an emission path of the light emitted through the light transmitting layer TPL. The light transmitting layer TPL may not include a wavelength conversion material.

The scatterer SCP may be a metal oxide particle or an organic particle. Examples of the metal oxide may include titanium oxide (TiO₂), zirconium oxide (ZrO₂), aluminum oxide (Al₂O₃), indium oxide (In₂O₃), zinc oxide (ZnO), tin oxide (SnO₂), and the like.

The first to third base resins BRS1, BRS2, and BRS3 may include a light transmitting organic material. For example, the first to third base resins BRS1, BRS2, and BRS3 may include an epoxy resin, an acrylic resin, a cardo resin, an imide resin, or the like. The first to third base resins BRS1, BRS2 and BRS3 may be formed of a same material, but the disclosure is not limited thereto.

The first wavelength conversion material WCP1 may convert the blue light of the third color into the red light of the first color, and the second wavelength conversion material WCP2 may convert the blue light of the third color into the green light of the second color. The first wavelength conversion material WCP1 and the second wavelength conversion material WCP2 may be quantum dots, quantum bars, phosphors or the like. Examples of the quantum dot may include a group IV nanocrystal, a group II-VI compound nanocrystal, a group III-V compound nanocrystal, a group IV-VI nanocrystal, and a combination thereof.

In some embodiments, the color control layer CCR may be formed by an inkjet printing process or a photoresist process. The color control layer CCR may be formed through drying or exposure and development processes after a material constituting the color control layer CCR is sprayed into or coated on the region surrounded by the upper bank layer UBN. For example, in the drawing of an embodiment in which the color control layer CCR is formed by an inkjet printing process, the top surface of each color control layer CCR may be formed to be curved, so that the edge portion thereof adjacent to the upper bank layer UBN is higher than the center portion thereof. However, the disclosure is not limited thereto. In an embodiment in which the color control layer CCR is formed by a photoresist process, the top surface of each color control layer CCR may be formed to be flat, so that the edge portion adjacent to the upper bank layer UBN is parallel to the top surface of the upper bank layer UBN. In another embodiment, unlike the drawing, the center portion of the color control layer CCR may be formed to be higher than the edge portion thereof.

The light emitting element ED of each sub-pixel SPXn may emit light of the same color that is the blue light, or the sub-pixels SPXn may emit lights of different colors. For example, the light emitted from the light emitting element ED disposed in the first sub-pixel SPX1 may be incident on the first wavelength conversion layer WCL1, the light emitted from the light emitting element ED disposed in the second sub-pixel SPX2 may be incident on the second wavelength conversion layer WCL2, and the light emitted from the light emitting element ED disposed in the third sub-pixel SPX3 may be incident on the light transmitting layer TPL.

The light incident on the first wavelength conversion layer WCL1 may be converted into red light, the light incident on the second wavelength conversion layer WCL2 may be converted into green light, and the light incident on the light transmitting layer TPL may be transmitted as the same blue light without wavelength conversion. Although each sub-pixel SPXn includes the light emitting elements ED which emit light of the same color, light of different colors may be emitted according to the arrangement of the color control layers CCR disposed there above.

The first capping layer CPL1 may be disposed on the color control layer CCR and the upper bank layer UBN. The first capping layer CPL1 may prevent impurities such as moisture or air from permeating from the outside and damaging or contaminating the color control layer CCR. The first capping layer CPL1 may include an inorganic insulating material.

The low refractive index layer LRL may be disposed on the first capping layer CPL1. The low refractive index layer LRL that is an optical layer for recycling the light transmitted through the color control layer CCR may improve the light emission efficiency and the color purity of the display device 10. The low refractive index layer LRL may be made of an organic material having a low refractive index, and may compensate a stepped portion formed by the color control layer CCR and the upper bank layer UBN.

The second capping layer CPL2 may be disposed on the low refractive index layer LRL, and may prevent impurities such as moisture, air, or the like from permeating from the outside and damaging or contaminating the low refractive index layer LRL. The second capping layer CPL2 may include an inorganic insulating material similarly to the first capping layer CPL1.

The color filter layer CFL may be disposed on the second capping layer CPL2. The color filter layer CFL may be disposed in the light transmitting areas TA1, TA2, and TA3, and a part thereof may be disposed in the light blocking area BA. A portion of a color filter layer CFL may overlap a portion of another color filter layer CFL or the color patterns CP1, CP2, and CP3 in the light blocking area BA. A portion where the color filter layers CFL do not overlap each other may be the light transmitting area TA1, TA2, or TA3 from which light is emitted. An area where the color filter layers CFL overlap each other or where the color patterns CP1, CP2, and CP3 are disposed may be the light blocking area BA in which light is blocked.

The color filter layer CFL may include a first color filter CFL1 disposed in the first sub-pixel SPX1, a second color filter CFL2 disposed in the second sub-pixel SPX2, and a third color filter CFL3 disposed in the third sub-pixel SPX3. Each of the color filters CFL1, CFL2, and CFL3 may be formed in a linear pattern disposed in the light transmitting areas TA1, TA2, and TA3 or the emission areas EMA. However, the disclosure is not limited thereto. The color filters CFL1, CFL2, and CFL3 may be disposed to correspond to the light transmitting areas TA1, TA2, and TA3, respectively, and may form an island-like pattern.

The color filter layer CFL may include a colorant such as a dye or a pigment that absorbs light of a wavelength other than a specific wavelength. Each of the color filters CFL1, CFL2, and CFL3 may be disposed in each sub-pixel SPXn and may transmit only a portion of light incident on each of the color filters CFL1, CFL2 and CFL3 in the corresponding sub-pixel SPXn. In each sub-pixel SPXn of the display device 10, only light transmitted through each of the color filters CFL1, CFL2, and CFL3 may be displayed. In an embodiment, the first color filter CFL1 may be a red color filter layer R, the second color filter CFL2 may be a green color filter layer G, and the third color filter CFL3 may be a blue color filter layer B. Lights emitted from the light emitting element ED may be emitted through the color control layer CCR and the color filter layer CFL.

The color patterns CP1, CP2, and CP3 may be disposed on the color filter layer CFL. The color patterns CP1, CP2, and CP3 may include the same material as the color filter layer CFL and may be disposed in the light blocking area BA. In the light blocking area BA, the color patterns CP1, CP2, and CP3 and the different color filters CFL1, CFL2, and CFL3 may be stacked each other, and light may be blocked in the stacked area.

The first color pattern CP1 may be made of the same material as that of the first color filter CFL1 and disposed in the light blocking area BA. The first color pattern CP1 may be directly disposed on the second capping layer CPL2 in the light blocking area BA, and may not be disposed in the light blocking area BA that is adjacent to the first light transmitting area TA1 of the first sub-pixel SPX1. The first color pattern CP1 may be disposed in the light blocking area BA between the second sub-pixel SPX2 and the third sub-pixel SPX3. The first color filter CFL1 may be disposed in the light blocking area BA around the first sub-pixel SPX1.

The second color pattern CP2 may be made of the same material as that of the second color filter CFL2 and disposed in the light blocking area BA. The second color pattern CP2 may be disposed on the second capping layer CPL2 in the light blocking area BA, and may not be disposed in the light blocking area BA that is adjacent to the second light transmitting area TA2 of the second sub-pixel SPX2. The second color pattern CP2 may be disposed in the light blocking area BA between the first sub-pixel SPX1 and the third sub-pixel SPX3 or at the boundary between the outermost sub-pixel SPXn of the display area DPA and the non-display area NDA. The second color filter CFL2 may be disposed in the light blocking area BA around the second sub-pixel SPX2.

Similarly, the third color pattern CP3 may be made of the same material as that of the third color filter CFL3 and disposed in the light blocking area BA. The third color pattern CP3 may be disposed on the second capping layer CPL2 in the light blocking area BA, and may not be disposed in the light blocking area BA that is adjacent to the third light transmitting area TA3 of the third sub-pixel SPX3. The third color pattern CP3 may be disposed in the light blocking area BA between the first sub-pixel SPX1 and the second sub-pixel SPX2. The third color filter CFL3 may be disposed in the light blocking area BA around the third sub-pixel SPX3.

In the display device 10, an area where the bank layer BNL and the upper bank layer UBN overlap each other may be the light blocking area BA. In the light blocking area BA, one of the first color pattern CP1, the second color pattern CP2, and the third color pattern CP3 may be disposed to overlap at least one of the color filters CFL1, CFL2, and CFL3, which includes a different color material. For example, the first color pattern CP1 may be disposed to overlap the second color filter CFL2 and the third color filter CFL3, the second color pattern CP2 may be disposed to overlap the first color filter CFL1 and the third color filter CFL3, and the third pattern CP3 may be disposed to overlap the first color filter CFL1 and the second color filter CFL2. In the light blocking area BA, the color patterns CP1, CP2, and CP3, and the color filters CFL1, CFL2, and CFL3, which include different color materials, may overlap each other, thereby blocking light.

The color patterns CP1, CP2, and CP3 and the color filters CFL1, CFL2, and CFL3 may constitute the stacked structure and include a material including a different color material, thereby preventing the color mixture between adjacent areas. As the color patterns CP1, CP2, and CP3 include the same material as the color filters CFL1, CFL2, and CFL3, external light or reflected light, which has passed through the light blocking area BA, may have a wavelength band of a specific color. The eye color sensibility perceived by user's eyes varies depending on the color of the light. In particular, the light in the blue wavelength band may be perceived less sensitively to a user than the light in the green wavelength band and the light in the red wavelength band. In the display device 10, the color patterns CP1, CP2, and CP3 are disposed in the light blocking area BA, so that light may be blocked and a user may perceive the reflected light relatively less sensitively. Further, by absorbing a portion of light entering from the outside of the display device 10, it is possible to reduce the reflected light due to the external light.

The overcoat layer OC may be disposed on the color filter layer CFL and the color patterns CP1, CP2, and CP3. The overcoat layer OC may be disposed in the entire display area DPA, and may be partially disposed in the non-display area NDA. The overcoat layer OC may protect the members including an organic insulating material and arranged in the display area DPA from the outside.

The display device 10 according to one embodiment may include the color control layer CCR and the color filter layer CFL disposed above the light emitting elements ED. Therefore, even in case that a same type of the light emitting elements ED are disposed in each sub-pixel SPXn, the display device 10 may display light of different colors.

For example, the light emitting element ED disposed in the first sub-pixel SPX1 may emit the blue light of the third color, and the light may be incident on the first wavelength conversion layer WCL1 while transmitting the fourth insulating layer PAS4. The first base resin BRS1 of the first wavelength conversion layer WCL1 may be made of a transparent material, and a portion of the light may transmit the first base resin BRS1 and be incident on the first capping layer CPL1 disposed thereon. However, at least a portion of the light may be incident on the scatterer SCP and the first wavelength conversion material WCP1 arranged in the first base resin BRS1. The light may be scattered and subjected to wavelength conversion, and may be incident as red light on the first capping layer CPL1. The lights incident on the first capping layer CPL1 may be incident on the first color filter CFL1 while transmitting the low refractive layer LRL, and the second capping layer CPL2, and the transmission of other lights except the red light may be blocked by the first color filter CFL1. Accordingly, the first sub-pixel SPX1 may emit the red light.

Similarly, the lights emitted from the light emitting element ED disposed in the second sub-pixel SPX2 may be emitted as the green light while transmitting the fourth insulating layer PAS4, the second wavelength conversion layer WCL2, the first capping layer CPL1, the low refractive index layer LRL, the second capping layer CPL2, and the second color filter CFL2.

The light emitting element ED disposed in the third sub-pixel SPX3 may emit the blue light of the third color, and the blue light may be incident on the light transmitting layer while transmitting the fourth insulating layer PAS4. The third base resin BRS3 of the light transmitting layer TPL may be made of a transparent material, and a portion of the light may transmit the third base resin BRS3 and be incident on the first capping layer CPL1 disposed thereon. The lights incident on the first capping layer CPL1 may be incident on the third color filter CFL3 while transmitting the low refractive index layer LRL and the second capping layer CPL2, and the transmission of other lights except the blue light may be blocked by the third color filter CFL3. Accordingly, the third sub-pixel SPX3 may emit the blue light.

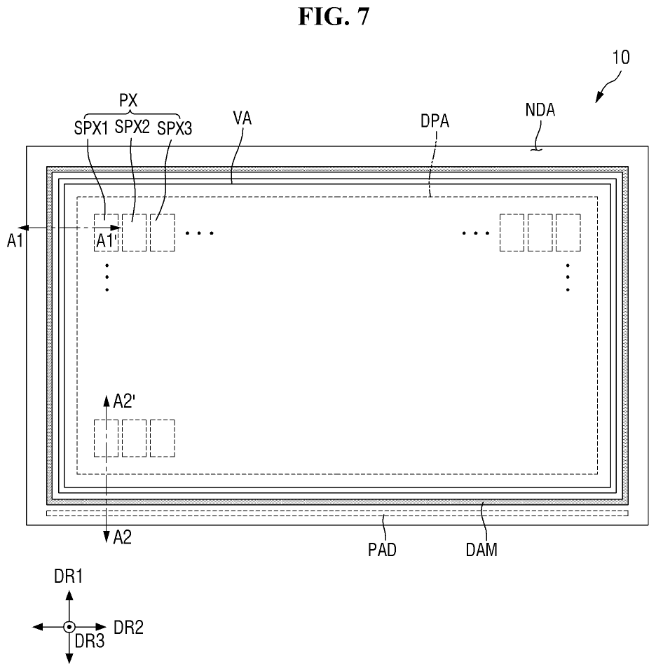

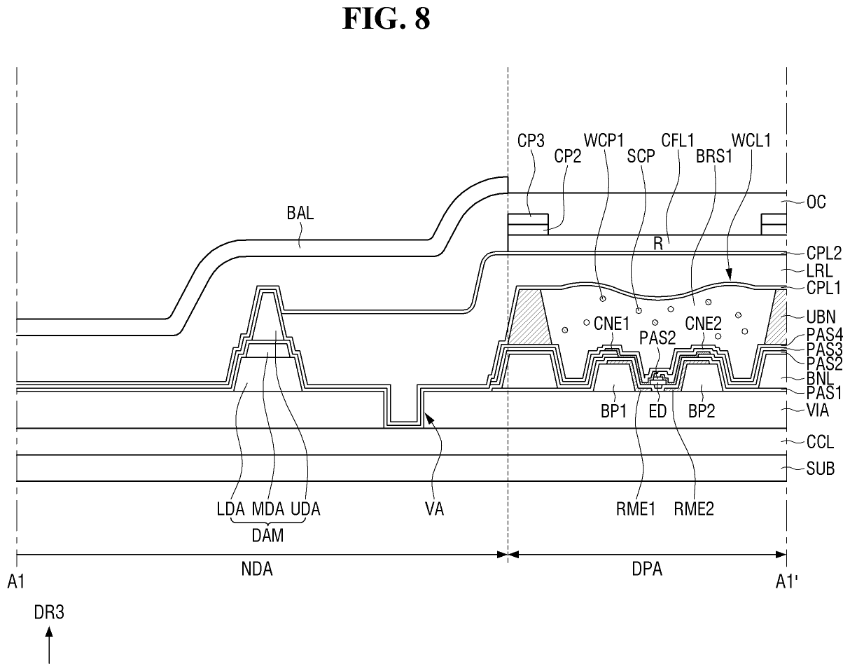

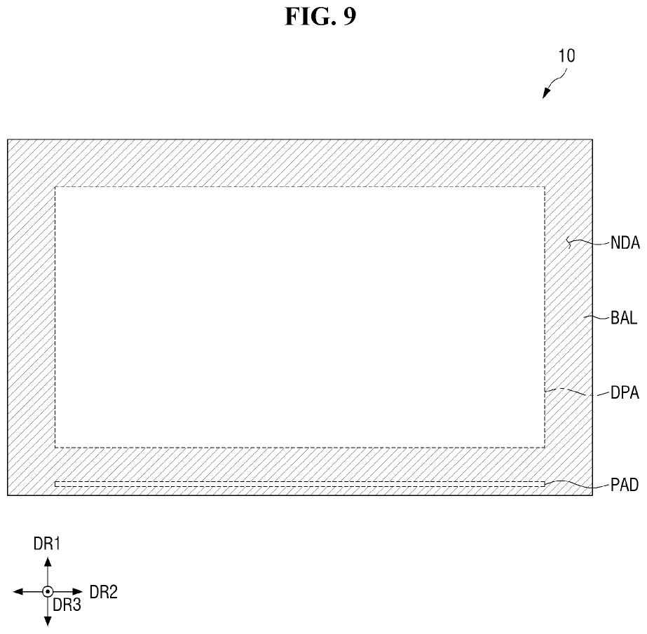

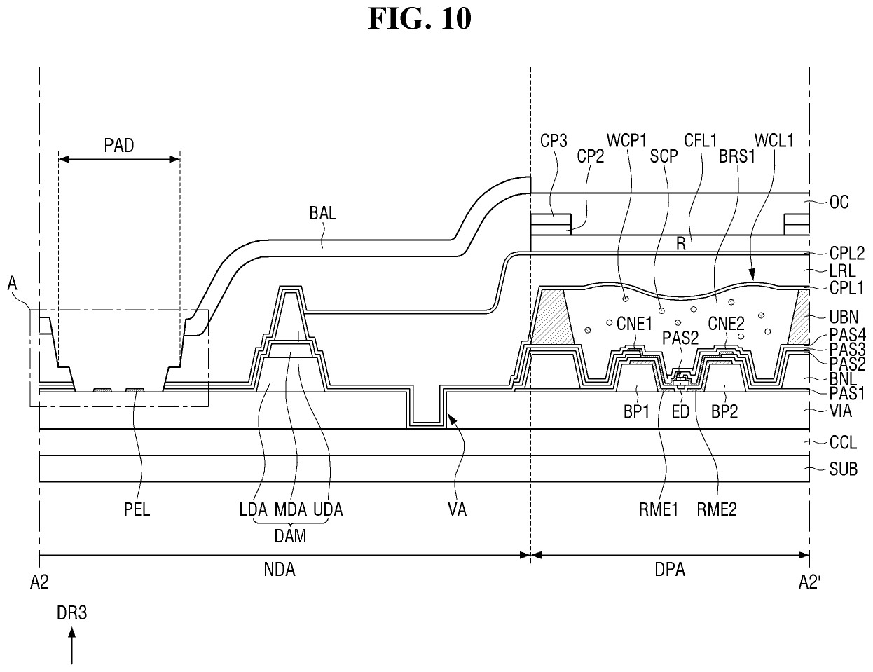

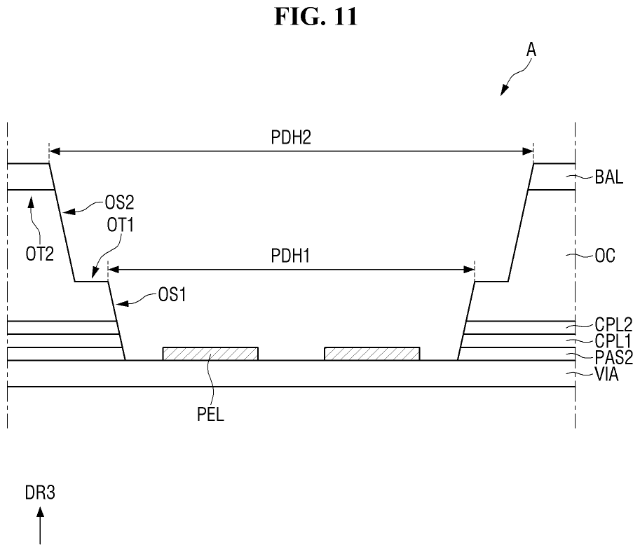

FIG. 7 is a plan view schematically illustrating a display device according to one embodiment. FIG. 8 is a schematic cross-sectional view taken along line A1-A1′ of FIG. 7. FIG. 9 is a plan view schematically illustrating a barrier layer of a display device according to one embodiment. FIG. 10 is a schematic cross-sectional view taken along line A2-A2′ of FIG. 7. FIG. 11 is an enlarged view of area A of FIG. 10.

Referring to FIGS. 7 to 11, the display device 10 may include the upper bank layer UBN and the bank layer BNL that have portions disposed in the border of the display area DPA, and a hole portion VA and a dam structure portion DAM that are disposed in the non-display area NDA to surround the display area DPA.

The upper bank layer UBN and the bank layer BNL may extend in the first direction DR1 and the second direction DR2 in the display area DPA. As described above, the upper bank layer UBN may be disposed on the bank layer BNL, and they may have the same pattern shape in plan view. For example, the upper bank layer UBN and the bank layer BNL may be disposed in the border of the display area DPA to surround the portion in which the pixels PX are disposed. The upper bank layer UBN and the bank layer BNL may define the display area DPA from the non-display area NDA, and may also define different sub-pixels SPXn.

The dam structure portion DAM may be disposed in the non-display area NDA to surround the display area DPA while being spaced apart from the upper bank layer UBN and the bank layer BNL. The dam structure portion DAM may be disposed to be spaced apart from the upper bank layer UBN and the bank layer BNL by a distance. The display area DPA may be surrounded by the dam structure portion DAM.

The display device 10 may have a structure in which multiple layers are sequentially stacked on a substrate SUB. Some of the layers of the display device 10 may be made of an organic material, and may be formed by a process of directly injecting the organic material onto the substrate SUB. Since the organic material may flow with fluidity, the organic material injected onto the display area DPA may overflow to the non-display area NDA. The dam structure portion DAM may prevent the organic material from overflowing to the outside beyond the non-display area NDA.

The display device 10 according to one embodiment may include the hole portion VA disposed between the dam structure portion DAM, and the upper bank layer UBN and the bank layer BNL in the non-display area NDA. The dam structure portion DAM, the upper bank layer UBN, and the bank layer BNL may have a shape protruding upward from the via layer VIA, and the hole portion VA may be formed by partially recessing the via layer VIA. The hole portion VA may form concave and convex patterns with the dam structure portion DAM, the upper bank layer UBN, and the bank layer BNL, thereby preventing an organic material sprayed onto the display area DPA from overflowing to the non-display area NDA.

As an encapsulation structure disposed on the color control layer CCR, the first capping layer CPL1 and the second capping layer CPL2 may extend to the non-display area NDA. A portion of the first capping layer CPL1 may be directly disposed on the fourth insulating layer PAS4 as shown in FIG. 8, and another portion thereof may be disposed on the upper bank layer UBN, the dam structure portion DAM, and the hole portion VA. The first capping layer CPL1 may be disposed along a stepped portion that is formed by the color control layer CCR, the upper bank layer UBN, the dam structure portion DAM, and the hole portion VA.

The second capping layer CPL2 may be disposed on the first capping layer CPL1 with the low refractive index layer LRL interposed therebetween. Since the low refractive index layer LRL does not extend across the entire surface of the non-display area NDA unlike the second capping layer CPL2, a portion of the second capping layer CPL2 may be directly disposed on the first capping layer CPL1 in the non-display area NDA.

The low refractive index layer LRL may be made of an organic material and may be disposed in the entire display area DPA. In the process of coating the organic material on the first capping layer CPL1, the organic material may overflow beyond the upper bank layer UBN to the non-display area NDA disposed at the border of the display area DPA. For example, the display device 10 may include a single substrate SUB and multiple layers may be formed thereon through consecutive processes. In the processes, the organic material which has overflowed to an undesired region of the non-display area NDA may be a foreign material in the subsequent process. The display device 10 according to one embodiment may include a concave and a convex structure in the non-display area NDA to prevent the overflowed organic material from flowing to an undesired area.

Since the display device 10 includes the hole portion VA and the dam structure portion DAM disposed in the non-display area NDA, a structure, which forms concave and convex patterns with respect to the top surface of the via layer VIA, may be disposed therein. The hole portion VA may have a concave pattern shape that is recessed from the top surface of the via layer VIA toward the bottom surface thereof. The dam structure portion DAM may have a convex pattern shape that protrudes upward from the top surface of the via layer VIA.

The hole portion VA may be disposed to be spaced apart from the upper bank layer UBN while surrounding the display area DPA in plan view. The hole portion VA may have a width and may pass through the via layer VIA. Some layers disposed on the via layer VIA may be disposed in the hole portion VA. For example, a portion of the second insulating layer PAS2 may be disposed in the hole portion VA. The second insulating layer PAS2 may be disposed along a stepped portion formed by the hole portion VA. A portion of the first capping layer CPL1 may be disposed in the hole portion VA. The first capping layer CPL1 may include an inorganic insulating material, and may be disposed along the stepped portion formed by the hole portion VA in the via layer VIA. As an inorganic insulating material such as the first capping layer CPL1 is disposed in the hole portion VA, it is possible to prevent the via layer VIA from acting as a moisture permeation path.

The low refractive index layer LRL may be disposed on the first capping layer CPL1 and a part thereof may be disposed in the non-display area NDA over the upper bank layer UBN disposed on the border of the display area DPA. The low refractive index layer LRL may also be disposed on the hole portion VA, and a part thereof may be disposed to fill the stepped portion formed by the hole portion VA. In the process of forming the low refractive index layer LRL, the organic material forming the low refractive index layer LRL may flow to the non-display area NDA beyond the display area DPA and fill the stepped portion formed by the hole portion VA. The hole portion VA and the dam structure portion DAM may prevent an excessive overflow of the organic material. The low refractive index layer LRL may extend to the dam structure portion DAM while filling the hole portion VA.

The dam structure portion DAM may surround the hole portion VA and may be spaced apart from the hole portion VA. The hole portion VA and the dam structure portion DAM may be disposed sequentially in the direction from the upper bank layer UBN to the outer portion of the non-display area NDA, while being spaced apart from each other. As the dam structure portion DAM has a shape protruding upward from the via layer VIA and has convex pattern shape, it is possible to prevent the low refractive index layer LRL from overflowing to the outer portion of the non-display area NDA.

As a structure for preventing the overflow of the low refractive index layer LRL, the dam structure portion DAM may be disposed in the non-display area NDA. The dam structure portion DAM may be disposed on the via layer VIA and may surround the border of the display area DPA. The dam structure portion DAM may surround the display area DPA. The dam structure portion DAM may be spaced apart from the display area DPA by a distance to be disposed in the non-display area NDA. The dam structure portion DAM may be spaced apart from the hole portion VA by a distance to surround the hole portion VA. The dam structure portion DAM may be continuously disposed and may continuously surround the display area DPA. In an embodiment, the dam structure portion DAM may have a closed loop shape in plan view. The dam structure DAM may be continuously disposed to prevent an organic material such as the low refractive index layer LRL extending from the display area DPA from overflowing to the outside of the substrate SUB.

The dam structure portion DAM may include a lower dam layer LDA, an intermediate dam layer MDA, and an upper dam layer UDA that are disposed on the via layer VIA.

The lower dam layer LDA may be directly disposed on the via layer VIA. The lower dam layer LDA and the bank patterns BP1 and BP2 may include a same material. The top surface of the lower dam layer LDA and the top surface of the bank patterns BP1 and BP2 may have a same height. In an embodiment, the lower dam layer LDA and the bank patterns BP1 and BP2 may be formed simultaneously in a same process.

The intermediate dam layer MDA may be directly disposed on the lower dam layer LDA. The intermediate dam layer MDA may overlap the lower dam layer LDA and may contact the top surface of the lower dam layer LDA. The intermediate dam layer MDA may have a width less than a width of the lower dam layer LDA in the second direction DR2 to be directly disposed on the lower dam layer LDA. However, the disclosure is not limited thereto, and the intermediate dam layer MDA may be in direct contact with the via layer VIA while covering the lower dam layer LDA, and the width of the intermediate dam layer MDA may be greater than the width of the lower dam layer LDA. The intermediate dam layer MDA and the bank layer BNL may include a same material. The top surface of the intermediate dam layer MDA and the top surface of the bank layer BNL may have a same height. In an embodiment, the intermediate dam layer MDA and the bank layer BNL may be simultaneously formed in a same process.

The upper dam layer UDA may be directly disposed on the intermediate dam payer MDA. The upper dam layer UDA may be disposed on the intermediate dam layer MDA to cover the intermediate dam layer MDA and the lower dam layer LDA, and may overlap the intermediate dam layer MDA and the lower dam layer LDA. A width of the upper dam layer UDA may be less than the width of the intermediate dam layer MDA and the width of the lower dam layer LDA. The upper dam layer UDA and the upper bank layer UBN may include a same material. Atop surface of the upper dam layer UDA may have the same height as atop surface of the upper bank layer UBN. In an embodiment, the upper dam layer UDA may be formed simultaneously by the same process as the upper bank layer UBN.

The second insulating layer PAS2 may be disposed on the intermediate dam layer MDA and the lower dam layer LDA. The second insulating layer PAS2 may extend from the display area DPA to cover the intermediate dam layer MDA and the lower dam layer LDA.

The hole portion VA may be disposed closer to the display area DPA than the dam structure portion DAM, and may be a primary structure for preventing the overflow of the organic material. The hole portion VA may have a width to prevent the organic material from overflowing. The width of the hole portion VA may be less than or equal to the width of the dam structure portion DAM in the second direction DR2. However, the disclosure is not limited thereto, and the width of the hole portion VA may be greater than the width of the dam structure portion DAM.

The overcoat layer OC may be disposed to cover the color filter layer CFL in the display area DPA, and to cover the dam structure portion DAM and the second capping layer CPL2 in the non-display area NDA. The overcoat layer OC may have a shape in which the height of the top surface thereof gradually decreases as going from the display area DPA to the outermost portion of the non-display area NDA.

A barrier layer BAL may be disposed in the non-display area NDA. The barrier layer BAL may be disposed on the overcoat layer OC in the non-display area NDA. The barrier layer BAL may be disposed in the display area DPA and may be disposed in the non-display area NDA.

The barrier layer BAL may block external moisture from infiltrating into the inside. The barrier layer BAL may be disposed to cover the overcoat layer OC, the second capping layer CPL2, and the first capping layer CPL1 disposed in the non-display area NDA to prevent moisture from permeating therethrough. The overcoat layer OC may be made of an organic material and may act as a path for moisture to permeate, and the first capping layer CPL1 and the second capping layer CPL2 may be made of inorganic materials including silicon oxide (SiOₓ) making it hard to completely block moisture. For example, in case that a step or crack occurs between the first capping layer CPL1 and the second capping layer CPL2, it may act as a moisture permeation path. Accordingly, by forming the barrier layer BAL covering the overcoat layer OC, the second capping layer CPL2, and the first capping layer CPL1 in the non-display area NDA adjacent to the outside, external moisture may be prevented from infiltrating.

The barrier layer BAL may include silicon nitride (SiNₓ) having a moisture blocking property that is relatively superior to that of silicon oxide. The silicon nitride of the barrier layer BAL may have relatively lower light transmittance than silicon oxide. According to an embodiment, the barrier layer BAL may be disposed in the non-display area NDA and not in the display area DPA, thereby improving display quality by preventing a decrease in light transmittance of the display device 10.

The barrier layer BAL may be disposed in the non-display area NDA of the display device 10 but not in a pad portion PAD disposed in the non-display area NDA. For example, the barrier layer BAL may not be disposed in the pad portion PAD.

As shown in FIGS. 10 and 11, pad electrodes PEL may be disposed on the via layer VIA in the pad portion PAD of the non-display area NDA. The pad electrode PEL may be exposed to be connected to an external device through which an external signal is transmitted to the display device 10.

For example, the pad electrode PEL and the first electrode RME1 or the second electrode RME2 of FIG. 6 described above may include a same material. An alignment signal applied to the first electrode RME1 or the second electrode RME2 may be applied to the pad electrode PEL, or a gate signal or a data signal applied to the transistors (‘T1’ or ‘T2’ in FIG. 3) may be applied to the pad electrode PEL.

A first pad hole PDH1 exposing the pad electrodes PEL may be disposed on a portion of the second insulating layer PAS2, the first capping layer CPL1, the second capping layer CPL2, and the overcoat layer OC disposed on the via layer VIA. The first pad hole PDH1 may completely expose the pad electrodes PEL, and may also expose a top surface of the via layer VIA around the pad electrodes PEL. A second pad hole PDH2 exposing the first pad hole PDH1 and the pad electrodes PEL may be disposed on another portion of the overcoat layer OC and the barrier layer BAL. The second pad hole PDH2 may completely expose the first pad hole PDH1 and the pad electrodes PEL, and may partially expose the upper surface of the overcoat layer OC. The first pad hole PDH1 and the second pad hole PDH2 may overlap each other, and the first pad hole PDH1 may completely overlap the second pad hole PDH2 in plan view. A width of the first pad hole PDH1 may be less than a width of the second pad hole PDH2 in the second direction DR2. In the pad portion PAD, a conductive adhesive member such as an anisotropic conductive film may be filled in the pad holes PDH1 and PDH2 to be electrically connected to an external device.

The overcoat layer OC may have a step in the first pad hole PDH1 and the second pad hole PDH2. For example, the overcoat layer OC may include a first lateral side OS1 corresponding to the inner circumferential surface of the first pad hole PDH1, a second lateral side OS2 corresponding to the inner circumferential surface of the second pad hole PDH2, a first upper surface OT1 connecting the first lateral side OS1 and the second lateral side OS2, and a second upper surface OT2 corresponding to the uppermost surface of the overcoat layer OC. The first lateral side OS1 may be disposed closer to the pad electrode PEL in plan view than the second lateral side OS2. A length of the first lateral side OS1 in the third direction DR3 may be less than a length of the second lateral side OS2. The first upper surface OT1 and the second upper surface OT2 may be substantially parallel to each other, but the disclosure is not limited thereto.

The barrier layer BAL may be directly disposed on the top surface of the overcoat layer OC. The lateral side of the barrier layer BAL may be aligned with and coincide with the lateral side of the overcoat layer OC. For example, the lateral side of the barrier layer BAL corresponding to the inner circumferential surface of the second pad hole PDH2 and the second lateral side OS2 of the overcoat layer OC may be aligned with each other. The barrier layer BAL may not overlap the first pad hole PDH1 and the second pad hole PDH2.

As described above, in the display device 10 according to one embodiment, by forming the barrier layer BAL covering the structures disposed in the non-display area NDA, the permeation of external moisture may be prevented.

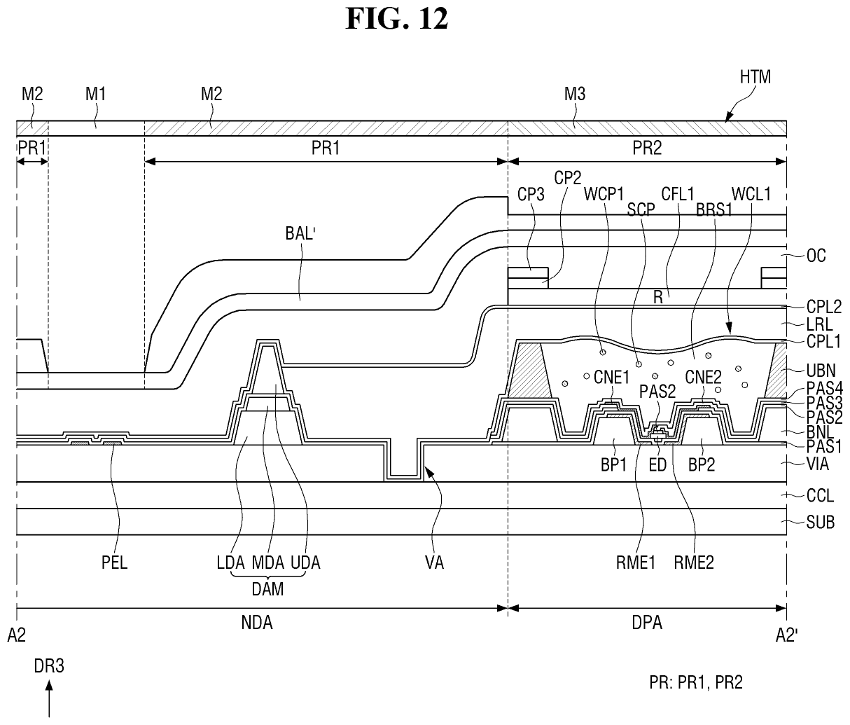

FIGS. 12 to 16 are schematic cross-sectional views illustrating each manufacturing process of a display device according to one embodiment. The manufacturing process of the display device shown in FIGS. 12 to 16 corresponds to the display device shown in FIG. 10. In FIGS. 12 to 16, the process from the substrate SUB to the overcoat layer OC will be omitted in the description.

Referring to FIG. 12, a barrier material layer BAL′ may be formed on the overcoat layer OC. The barrier material layer BAL′ may be formed over the entire display area DPA and the non-display area NDA of the substrate SUB, and may be formed of silicon nitride (SiNₓ).

A photoresist layer (not shown) may be formed on the barrier material layer BAL′ using a solution coating method such as spin coating, and a photoresist pattern PR may be formed by exposing and developing using a mask.

For example, a mask HTM, which is a half-tone mask, may be disposed on a photoresist layer (not shown). The mask HTM may include a transmissive region M1 through which light is transmitted, a blocking region M2 through which light is blocked, and a semi-transmissive region M3 through which the amount of light transmitted is adjusted. An exposure process of irradiating ultraviolet light (UV) toward the substrate SUB may be performed on the mask HTM. As for the disposition of the mask HTM, the blocking region M2 of the mask HTM may correspond to a portion where the barrier layer is to be formed, the semi-transmissive region M3 may correspond to the portion where the barrier layer is to be removed, and transmissive region M1 may be arranged to correspond to the remaining area. Accordingly, the portion corresponding to the blocking region M2 may be not irradiated with UV, the portion corresponding to the transmissive region M1 may be irradiated with UV, and the portion corresponding to the semi-transmissive region M3 may be irradiated with UV in which the amount thereof is adjusted.

A developing process may be performed by applying a developer to the exposed photoresist layer, thereby forming a photoresist pattern PR. According to the developing process, a first photoresist region PR1 having a first thickness may be formed in a portion where the barrier layer is to be formed, and a second photoresist region PR2 having a second thickness thinner than the first thickness may be formed in a portion where the barrier layer is to be partially removed. In the remaining portions, the photoresist layer may be completely removed to expose the barrier material layer BAL′.

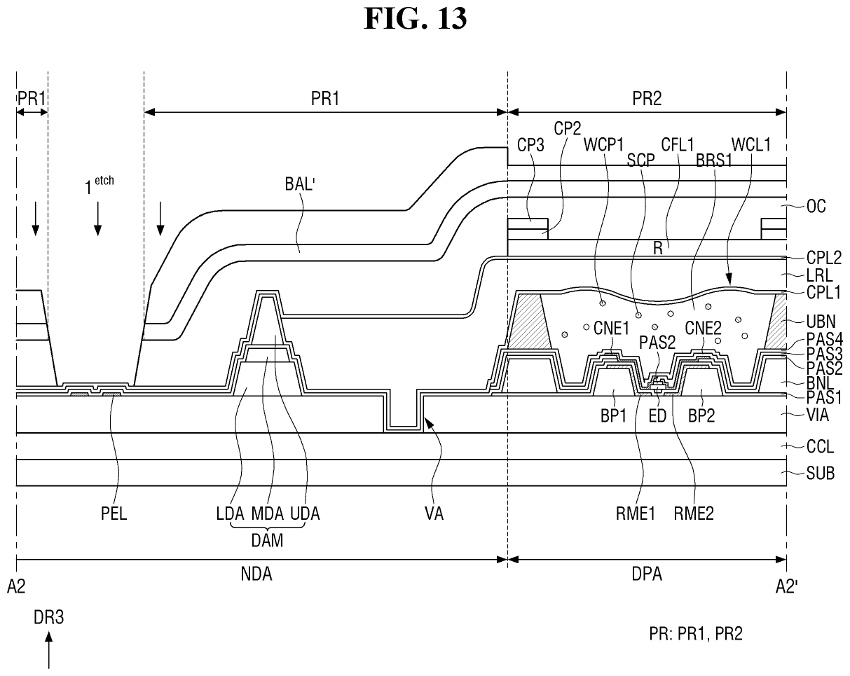

Referring to FIG. 13, the barrier material layer BAL′ and the overcoat layer OC may be first-etched letch using an etchant in areas other than the first photoresist region PR1 and the second photoresist region PR2. As the barrier material layer BAL′ and the overcoat layer OC are removed, the second capping layer CPL2 may be exposed. An etchant capable of simultaneously etching the barrier material layer BAL′ and the overcoat layer OC may be used as the etchant for etching the barrier material layer BAL′ and the overcoat layer OC.

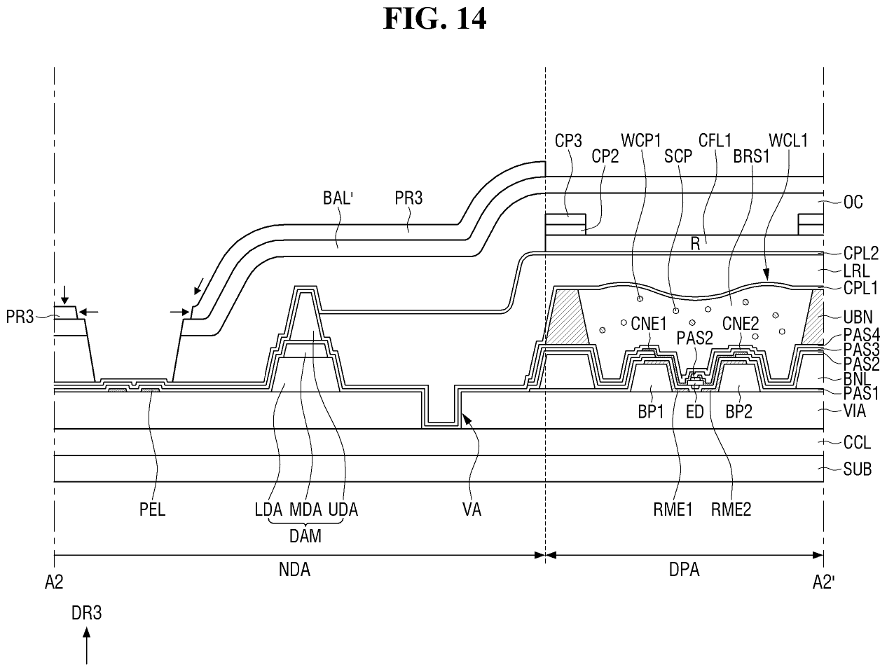

Referring to FIG. 14, an ashing process may be performed on the photoresist pattern PR remaining on the substrate SUB. The ashing process may be performed to reduce the thickness and size of the first photoresist region PR1 and to remove the second photoresist region PR2 having a second thickness. Accordingly, the second photoresist region PR2 having the second thickness may be removed by the ashing process, and the size of the first photoresist region PR1 may be reduced to form a third photoresist region PR3 having a third thickness. The side surface of the third photoresist region PR3 may be formed to be spaced apart inwardly from the side surface of the barrier material layer BAL′ located thereunder because the thickness and area are reduced by ashing. For example, the side surface of the barrier material layer BAL′ may protrude outward from the side surface of the third photoresist region PR3. As the second photoresist region PR2 is removed, a portion of the barrier material layer BAL′ covered with the existing second photoresist region PR2 may be exposed.

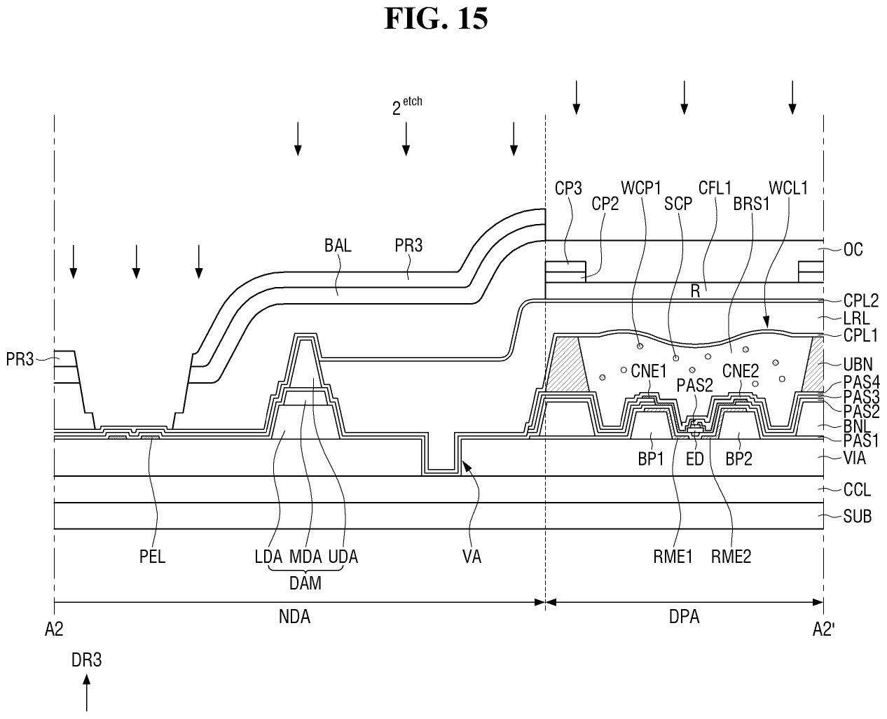

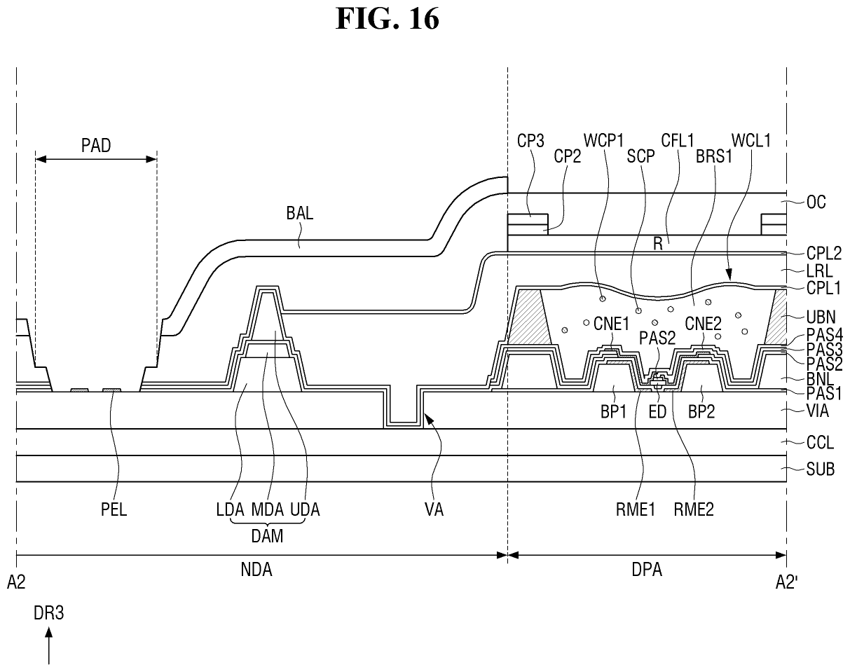

Referring to FIGS. 15 and 16, a second etching 2^{etch} may be performed on the substrate SUB on which the photoresist pattern PR including the third photoresist region PR3 is formed.

For example, a barrier layer BAL may be formed in the non-display area NDA by removing the barrier material layer BAL′ that does not overlap the third photoresist region PR3 of the photoresist pattern PR through the second etching process. By removing the second insulating layer PAS2, the first capping layer CPL1, and the second capping layer CPL2 that do not overlap the third photoresist region PR3 of the photoresist pattern PR, the pad electrode PEL may be exposed. Moreover, the overcoat layer OC that does not overlap the third photoresist region PR3 of the photoresist pattern PR may be partially removed to form a step.

As the step of the overcoat layer OC is formed in the second etching 2^{etch} process, the first pad hole PDH1 and the second pad hole PDH2 may be formed in the pad portion PAD. The first pad hole PDH1 may correspond to a lower portion of the overcoat layer OC etched in the first etching 1^{etch} process, and the second pad hole PDH2 may correspond to an upper portion of the overcoat layer OC etched in the second etching 2^{etch} process.

As shown in FIG. 16, the display device 10 may be manufactured by stripping and removing all the photoresist patterns PR existing on the substrate SUB.

As described above, in the method of manufacturing a display device according to one embodiment, the barrier layer BAL may be formed simultaneously with the process of forming the pad hole using a halftone mask, thereby saving the manufacturing costs by omitting a separate mask for forming the barrier layer BAL.

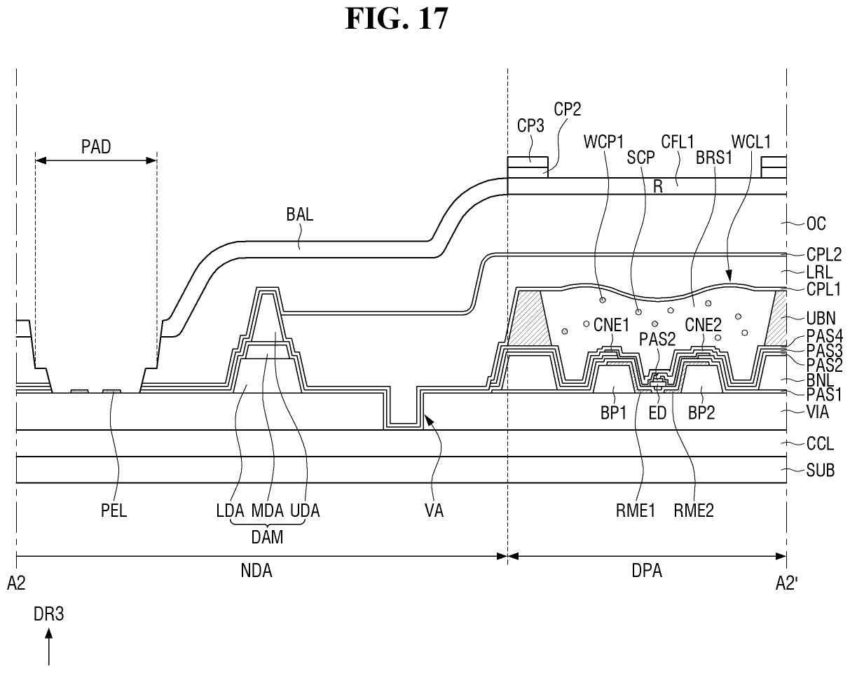

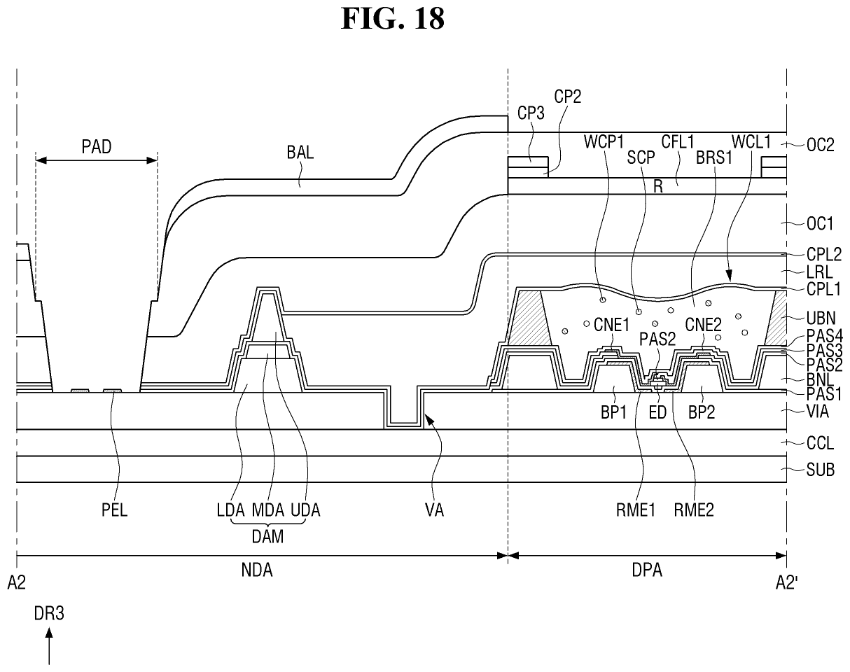

FIGS. 17 and 18 are schematic cross-sectional views schematically illustrating a display device according to another embodiment. FIGS. 17 and 18 illustrate a display device of other embodiments taken along line A2-A2′ of FIG. 7.

In each of the embodiments of FIGS. 17 and 18, it is illustrated that the arrangement of the overcoat layer can be variously formed according to needs.

Referring to FIG. 17, the embodiment is different from FIG. 10 in that the color filter layer CFL and the color patterns CP1, CP2, and CP3 are disposed on the overcoat layer OC.

The overcoat layer OC may serve as a planarization layer to planarize the lower step. The color filter layer CFL and the color patterns CP1, CP2, and CP3 may be disposed on the flat overcoat layer OC to improve patternability and improve display quality of the display device.

Referring to FIG. 18, in the embodiment, the first overcoat layer OC1 may be disposed under a color filter layer CFL, and a second overcoat layer OC2 may be disposed on the color filter layer CFL. The barrier layer BAL may be disposed on the second overcoat layer OC2 in the non-display area NDA. A step may be formed in the pad portion PAD. On the other hand, the step may be not formed on the first overcoat layer OC1.

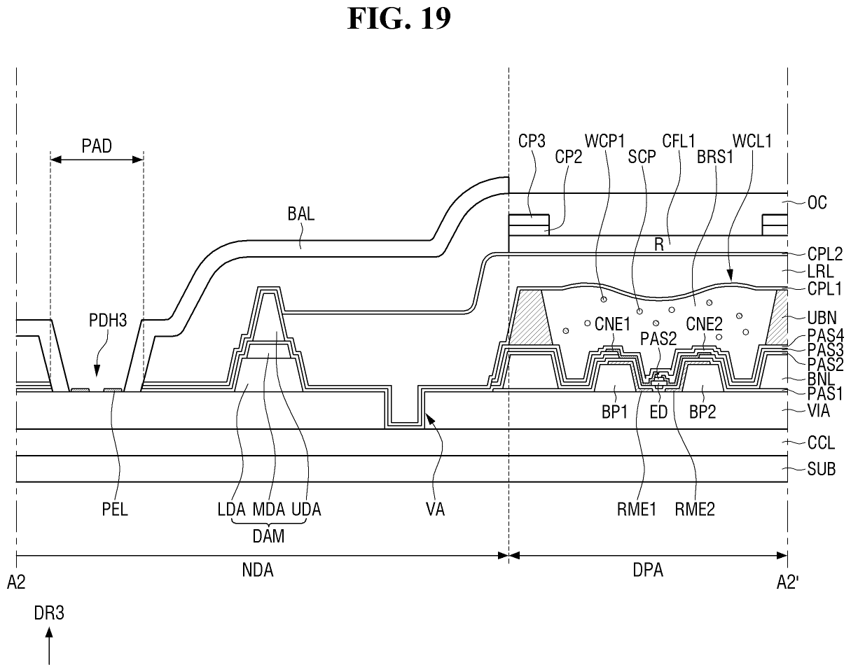

FIG. 19 is a schematic cross-sectional view illustrating a display device according to still another embodiment. FIG. 19 illustrates a display device of another embodiment taken along line A2-A2′ of FIG. 7.

Referring to FIG. 19, the embodiment is different from FIG. 10 in that the barrier layer BAL extends to the inside of a third pad hole PDH3 of the pad portion PAD. Hereinafter, descriptions overlapping the embodiment of FIG. 10 as described above will be omitted and differences will be described.

The third pad hole PDH3 exposing the pad electrodes PEL may be disposed in the pad portion PAD of the non-display area NDA. The third pad hole PDH3 exposing the pad electrodes PEL may be disposed on the second insulating layer PAS2, the first capping layer CPL1, the second capping layer CPL2, and the overcoat layer OC disposed on the via layer VIA. The third pad hole PDH3 may completely expose the pad electrodes PEL and may also expose the top surface of the via layer VIA around the pad electrodes PEL. In the third pad hole PDH3, lateral sides of each of the second insulating layer PAS2, the first capping layer CPL1, the second capping layer CPL2, and the overcoat layer OC may be aligned and coincide with each other.

The barrier layer BAL may be disposed in the non-display area NDA and may extend to the pad portion PAD. The barrier layer BAL may be disposed directly on the upper surface of the overcoat layer OC, and disposed to directly contact the lateral side of the overcoat layer OC corresponding to the inner circumferential surface of the third pad hole PDH3, the lateral side of the second capping layer CPL2, the lateral side of the first capping layer CPL1, and the lateral side of the second insulating layer PAS2. The barrier layer BAL may be disposed to be directly in contact with the top surface of the via layer VIA exposed by the third pad hole PDH3. The barrier layer BAL may be formed using a separate photo process after the third pad hole PDH3 is formed.

According to one embodiment, the barrier layer BAL may be disposed to cover the side of the overcoat layer OC. As described above, the overcoat layer OC may be made of an organic material and may act as a path for moisture permeation. The barrier layer BAL may cover the side of the overcoat layer OC to prevent permeation of moisture.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments.

What is claimed is:

1. A display device, comprising:
a display area and a non-display area;
light emitting elements disposed on a substrate in the display area;
an overcoat layer disposed on the light emitting elements and extending from the display area to the non-display area; and
a barrier layer disposed on the overcoat layer in the non-display area,
wherein the barrier layer is not disposed in the display area and comprises silicon nitride.

2. The display device of claim 1, wherein
the non-display area comprises a pad portion in which pad electrodes are disposed, and
the barrier layer is not disposed in the pad portion.

3. The display device of claim 2, wherein the barrier layer surrounds the display area and the pad portion in plan view.

4. The display device of claim 2, wherein the pad portion comprises:
a first pad hole exposing the pad electrodes; and
a second pad hole overlapping the first pad hole in plan view.

5. The display device of claim 4, wherein a width of the first pad hole is less than a width of the second pad hole in a direction perpendicular to a thickness direction of the substrate.

6. The display device of claim 4, wherein
the first pad hole penetrates the overcoat layer, and
the second pad hole penetrates the overcoat layer and the barrier layer.

7. The display device of claim 6, wherein the overcoat layer comprises:
a first lateral side corresponding to an inner circumferential surface of the first pad hole;
a second lateral side corresponding to an inner circumferential surface of the second pad hole;
a first top surface connecting the first lateral side and the second lateral side; and
a second top surface parallel to the first top surface and connected to the second lateral side.

8. The display device of claim 7, wherein a lateral side of the barrier layer and the second lateral side of the overcoat layer are aligned and coincide with each other in the second pad hole.

9. The display device of claim 7, wherein the barrier layer contacts the second top surface of the overcoat layer.

10. The display device of claim 1, further comprising:
a dam and a hole portion, each disposed in the non-display area and surrounding the display area in plan view,
wherein the overcoat layer and the barrier layer overlap the dam and the hole portion in plan view.

11. The display device of claim 1, further comprising:
a first capping layer disposed on the light emitting elements;
a low refractive layer disposed on the first capping layer;
a second capping layer disposed on the low refractive layer; and
a color filter layer disposed on the second capping layer.

12. The display device of claim 11, wherein the overcoat layer is disposed on the color filter layer.

13. The display device of claim 11, wherein the overcoat layer is interposed between the color filter layer and the second capping layer.

14. A display device, comprising:
a display area and a non-display area;
light emitting elements disposed on a substrate in the display area;
an overcoat layer disposed on the light emitting elements and extending from the display area to the non-display area; and
a barrier layer disposed on the overcoat layer in the non-display area, wherein
the non-display area comprises a pad portion in which pad electrodes are disposed, and
the barrier layer is not disposed in the display area, disposed in the pad portion of the non-display area, and comprises silicon nitride.

15. The display device of claim 14, wherein
the pad portion comprises a pad hole penetrating the overcoat layer and exposing the pad electrodes, and
the barrier layer is disposed in the pad hole.

16. The display device of claim 15, further comprising:
a via layer interposed between the substrate and the light emitting elements and extending from the display area to the non-display area,
wherein the pad hole exposes a top surface of the via layer.

17. The display device of claim 16, wherein the barrier layer contacts the top surface of the via layer in the pad hole.

18. The display device of claim 15, wherein the barrier layer covers a lateral side of the overcoat layer corresponding to an inner circumferential surface of the pad hole and contacts the lateral side of the overcoat layer.

19. The display device of claim 14, further comprising:
a first electrode and a second electrode disposed on the substrate and spaced apart from each other;
a first insulating layer disposed on the first electrode and the second electrode;
a first contact electrode disposed on the first insulating layer and in electrical contact with one ends of the light emitting elements; and
a second contact electrode disposed on another ends of the light emitting elements,
wherein the light emitting elements are disposed on the first electrode and the second electrode.

20. The display device of claim 19, wherein each of the light emitting elements comprise:
a first semiconductor layer comprising a p-type semiconductor;
a second semiconductor layer disposed on the first semiconductor layer and comprising an n-type semiconductor; and
an emission layer disposed between the first semiconductor layer and the second semiconductor layer.
